(19) United States
(12) Patent Application Publication
(10) Pub. No.: US 2026/0082861 A1
(43) Pub. Date: Mar. 19, 2026

(54) ELECTRONIC DEVICE, DEPOSITION APPARATUS AND METHOD FOR MANUFACTURING DISPLAY DEVICE BY USING THE SAME

(71) Applicant: Samsung Display Co., Ltd., Yongin-si (KR)

(72) Inventors: MUN SEONG JANG, Yongin-si (KR); MINSEOK KIM, Yongin-si (KR); SUNGYONG KO, Yongin-si (KR)

(21) Appl. No.: 19/267,235

(22) Filed: Jul. 11, 2025

(30) Foreign Application Priority Data
Sep. 19, 2024 (KR) 10-2024-0126942

(51) Int. Cl. H01L 21/683; B23B 31/28; H10K 59/12; H10K 71/00

(52) U.S. Cl. CPC H10P 72/722; B23B 31/28; H10K 59/12; H10K 71/00

(57) ABSTRACT

Disclosed is a deposition apparatus including a first electrostatic chuck configured to suction a support plate defining a pass hole, the first electrostatic chuck including a base part, and a suction part on the base part, the suction part defining a first recess for overlapping the pass hole, and second recesses spaced apart from the first recess, and having diameters that are less than a diameter of the first recess.

### CROSS-REFERENCE TO RELATED APPLICATION

The present application claims priority to, and the benefit of, Korean Patent Application No. 10-2024-0126942, filed on Sep. 19, 2024, in the Korean Intellectual Property Office, the entire disclosure of which is incorporated herein by reference.

### BACKGROUND

### 1. Field

Embodiments of the present disclosure described herein relate to a deposition apparatus that achieves an improved yield rate by including a recess that is formed to correspond to an area that overlaps a camera hole or a sensor hole of a target panel, and a method for manufacturing a display device by using the deposition apparatus.

### 2. Description of the Related Art

Electronic devices, such as smart phones, tablets, laptop computers, and smart televisions, are being developed. These electronic devices include a display device to provide information. A process of a display device includes a thin film deposition process of forming a thin film of a corresponding material on a surface of a substrate, a photolithography process of exposing a selected portion of the thin film, and a dry or wet etching process of removing am exposed portion of the thin film and patterning it into a desired shape, which are repeated several times, and among them, the dry etching process including the thin film deposition process are usually performed in a closed process chamber, and an electrostatic chuck for fixing a substrate is provided each process chamber. An electrostatic chuck may fix a target substrate through a suction force using air pressure and a suction force using static electricity.

### SUMMARY

Embodiments of the present disclosure provide a deposition apparatus with an improved yield rate, and a method for manufacturing a display device using the same.

According to one or more embodiments, a deposition apparatus includes a first electrostatic chuck configured to suction a support plate defining a pass hole, the first electrostatic chuck including a base part, and a suction part on the base part, the suction part defining a first recess for overlapping the pass hole, and second recesses spaced apart from the first recess, and having diameters that are less than a diameter of the first recess.

The first recess may completely pass through the suction part.

The base part may define a base recess overlapping the first recess.

The base recess may completely pass through the base part.

The suction part may include polyimide.

The base part may include ceramic or metal.

A profile of the suction part on a plane is less than that of the base part.

The suction part may further include a first surface parallel to a first direction, wherein the first recess includes a side recess extending from the first surface.

The first recess may include a (1-1)-th recess, and a (1-2)-th recess spaced apart from the (1-1)-th recess in the first direction.

Depths of the (1-1)-th recess and the (1-2)-th recess may be between about 1 mm and about 40 mm.

A distance between the (1-1)-th recess and the (1-2)-th recess in the first direction may be between about 1 mm and about 5 mm.

The suction part may include a first part surrounding the (1-1)-th recess on a plane, and a second part surrounding the (1-2)-th recess on the plane.

A height of the first part may be substantially equal to a height of the second part.

The first part and the second part might not include polyimide.

An upper surface of the first part and an upper surface of the second part may be lower than an upper surface of the suction part.

A step difference between the upper surface of the suction part and the upper surfaces of the first part or the second part may be between about 1 mm and about 3 mm.

According to one or more embodiments, a method for manufacturing a display device includes positioning, in a chamber, a first electrostatic chuck including a base part, and a suction part on the base part and defining a first recess and second recesses, diameters of the second recesses being less than a diameter of the first recess, for suctioning a support plate defining a pass hole overlapping the first recess, positioning, in the chamber, a second electrostatic chuck for suctioning a display panel having a main display area, and a component area having a transmittance that is higher than that of the main display area, the first electrostatic chuck and the second electrostatic chuck facing each other, vacuuming an interior of the chamber, combining the display panel and the support plate such that the component area overlaps the pass hole, stopping an operation of the first electrostatic chuck, and spacing the support plate apart from the first electrostatic chuck.

A time interval between the combining of the display panel and the support plate and the stopping of the operation of the first electrostatic chuck may be between about 1 second and about 3 seconds.

The first recess may include a (1-1)-th recess, and a (1-2)-th recess spaced apart from the (1-1)-th recess in a first direction, and completely passes through the suction part, wherein the base part defines a base recess overlapping the first recess and completely passing through the base part.

According to one or more embodiments, an electronic device for providing an image includes a display device manufactured by positioning, in a chamber a first electrostatic chuck including a base part, and a suction part defining a first recess and second recesses having diameters that are less than that of the first recess on the base part, for suctioning a support plate defining a pass hole to overlap the first recess, and a second electrostatic chuck for suctioning a display panel having a main display area, and a component area having a transmittance that is higher than that of the main display area, the first electrostatic chuck and the second electrostatic chuck facing each other, vacuuming an interior of the chamber, combining the display panel and the support plate such that the component area overlaps the pass hole, stopping an operation of the first electrostatic chuck, and spacing the support plate apart from the first electrostatic chuck.

### BRIEF DESCRIPTION OF THE DRAWINGS

The above and other aspects of the present disclosure will become apparent by describing in detail embodiments thereof with reference to the accompanying drawings.

FIG. 1 is a perspective view of a display device according to one or more embodiments of the present disclosure.

FIG. 2 is a view illustrating a folding state of the display device illustrated in FIG. 1.

FIG. 3 is an exploded perspective view of the display device illustrated in FIG. 1.

FIG. 4 is a block diagram of the display device illustrated in FIG. 3.

FIG. 5 is a view illustrating a cross section of an electronic panel including the display panel illustrated in FIG. 3 by way of example.

FIG. 6 is a view illustrating a cross section of the display panel illustrated in FIG. 5 by way of example.

FIG. 7 is a plan view of the display module illustrated in FIG. 3.

FIG. 8 is a view illustrating a cross section of an electronic panel corresponding to any one pixel illustrated in FIG. 7 by way of example.

FIG. 9 is a cross-sectional view taken along the line I-I′ illustrated in FIG. 7.

FIG. 10A is a perspective view of a first electrostatic chuck included in a deposition apparatus according to one or more embodiments of the present disclosure.

FIGS. 10B and 10C are cross-sectional views taken along the line II-II′ illustrated in FIG. 10A, respectively.

FIG. 11 is a perspective view illustrating a state, in which a support plate is fixed on a first electrostatic chuck included in a deposition apparatus according to one or more embodiments of the present disclosure.

FIG. 12 is an exploded perspective view of the first electrostatic chuck and the support plate illustrated in FIG. 11.

FIGS. 13 to 17A are cross-sectional views taken along the line III-III′ illustrated in FIG. 11, respectively.

FIG. 17B is an enlarged cross-sectional view of AA′ of FIG. 17A.

FIG. 18 is a flowchart of a method for manufacturing a display device according to one or more embodiments of the present disclosure.

FIGS. 19 to 21 are cross-sectional views illustrating a part of a method for manufacturing a display device according to one or more embodiments of the present disclosure.

### DETAILED DESCRIPTION

Aspects of some embodiments of the present disclosure and methods of accomplishing the same may be understood more readily by reference to the detailed description of embodiments and the accompanying drawings. The described embodiments are provided as examples so that this disclosure will be thorough and complete, and will fully convey the aspects of the present disclosure to those skilled in the art. Accordingly, processes, elements, and techniques that are redundant, that are unrelated or irrelevant to the description of the embodiments, or that are not necessary to those having ordinary skill in the art for a complete understanding of the aspects of the present disclosure may be omitted. Unless otherwise noted, like reference numerals, characters, or combinations thereof denote like elements throughout the attached drawings and the written description, and thus, repeated descriptions thereof may be omitted.

The described embodiments may have various modifications and may be embodied in different forms, and should not be construed as being limited to only the illustrated embodiments herein. The use of “can,” “may,” or “may not” in describing an embodiment corresponds to one or more embodiments of the present disclosure.

A person of ordinary skill in the art would appreciate, in view of the present disclosure in its entirety, that each suitable feature of the various embodiments of the present disclosure may be combined or combined with each other, partially or entirely, and may be technically interlocked and operated in various suitable ways, and each embodiment may be implemented independently of each other or in conjunction with each other in any suitable manner unless otherwise stated or implied.

In the drawings, the relative sizes of elements, layers, and regions may be exaggerated for clarity and/or descriptive purposes. In other words, because the sizes and thicknesses of elements in the drawings are arbitrarily illustrated for convenience of description, the disclosure is not limited thereto. Additionally, the use of cross-hatching and/or shading in the accompanying drawings is generally provided to clarify boundaries between adjacent elements. As such, neither the presence nor the absence of cross-hatching or shading conveys or indicates any preference or requirement for particular materials, material properties, dimensions, proportions, commonalities between illustrated elements, and/or any other characteristic, attribute, property, etc., of the elements, unless specified.

Various embodiments are described herein with reference to sectional illustrations that are schematic illustrations of embodiments and/or intermediate structures. As such, variations from the shapes of the illustrations as a result of, for example, manufacturing techniques and/or tolerances, are to be expected. Further, specific structural or functional descriptions disclosed herein are merely illustrative for the purpose of describing embodiments according to the concept of the present disclosure. Thus, embodiments disclosed herein should not be construed as limited to the illustrated shapes of elements, layers, or regions, but are to include deviations in shapes that result from, for instance, manufacturing.

For example, an implanted region illustrated as a rectangle will, typically, have rounded or curved features and/or a gradient of implant concentration at its edges rather than a binary change from implanted to non-implanted region. Likewise, a buried region formed by implantation may result in some implantation in the region between the buried region and the surface through which the implantation takes place.

Spatially relative terms, such as “beneath,” “below,” “lower,” “lower side,” “under,” “above,” “upper,” “over,” “higher,” “upper side,” “side” (e.g., as in “sidewall”), and the like, may be used herein for ease of explanation to describe one element or feature's relationship to another element(s) or feature(s) as illustrated in the figures. It will be understood that the spatially relative terms are intended to encompass different orientations of the device in use or in operation, in addition to the orientation depicted in the figures. For example, if the device in the figures is turned over, elements described as “below,” “beneath,” “or “under” other elements or features would then be oriented “above” the other elements or features. Thus, the example terms “below” and “under” can encompass both an orientation of above and below. The device may be otherwise oriented (e.g., rotated 90 degrees or at other orientations) and the spatially relative descriptors used herein should be interpreted accordingly. Similarly, when a first part is described as being arranged “on” a second part, this indicates that the first part is arranged at an upper side or a lower side of the second part without the limitation to the upper side thereof on the basis of the gravity direction.

Further, the phrase “in a plan view” means when an object portion is viewed from above, and the phrase “in a schematic cross-sectional view” means when a schematic cross-section taken by vertically cutting an object portion is viewed from the side. The terms “overlap” or “overlapped” mean that a first object may be above or below or to a side of a second object, and vice versa. Additionally, the term “overlap” may include stack, face or facing, extending over, covering, or partly covering or any other suitable term as would be appreciated and understood by those of ordinary skill in the art. The expression “not overlap” may include meaning, such as “apart from” or “set aside from” or “offset from” and any other suitable equivalents as would be appreciated and understood by those of ordinary skill in the art. The terms “face” and “facing” may mean that a first object may directly or indirectly oppose a second object. In a case in which a third object intervenes between a first and second object, the first and second objects may be understood as being indirectly opposed to one another, although still facing each other.

It will be understood that when an element, layer, region, or component (e.g., an apparatus, a device, a circuit, a wire, an electrode, a terminal, a conductive film, etc.) is referred to as being “formed on,” “on,” “connected to,” or “(operatively, functionally, or communicatively) coupled to” another element, layer, region, or component, it can be directly formed on, on, connected to, or coupled to the other element, layer, region, or component, or indirectly formed on, on, connected to, or coupled to the other element, layer, region, or component such that one or more intervening elements, layers, regions, or components may be present. In addition, this may collectively mean a direct or indirect coupling or connection and an integral or non-integral coupling or connection. For example, when a layer, region, or component is referred to as being “electrically connected” or “electrically coupled” to another layer, region, or component, it can be directly electrically connected or coupled to the other layer, region, and/or component or one or more intervening layers, regions, or components may be present. The one or more intervening components may include a switch, a transistor, a resistor, an inductor, a capacitor, a diode and/or the like. Accordingly, a connection is not limited to the connections illustrated in the drawings or the detailed description and may also include other types of connections. In describing embodiments, an expression of connection indicates electrical connection unless explicitly described to be direct connection, and “directly connected/directly coupled,” or “directly on,” refers to one component directly connecting or coupling another component, or being on another component, without an intermediate component.

In addition, in the present specification, when a portion of a layer, a film, an area, a plate, or the like is formed on another portion, a forming direction is not limited to an upper direction but includes forming the portion on a side surface or in a lower direction. On the contrary, when a portion of a layer, a film, an area, a plate, or the like is formed “under” another portion, this includes not only a case where the portion is “directly beneath” another portion but also a case where there is further another portion between the portion and another portion. Meanwhile, other expressions describing relationships between components, such as “between,” “immediately between” or “adjacent to” and “directly adjacent to,” may be construed similarly. It will be understood that when an element or layer is referred to as being “between” two elements or layers, it can be the only element or layer between the two elements or layers, or one or more intervening elements or layers may also be present.

For the purposes of this disclosure, expressions such as “at least one of,” or “any one of,” or “one or more of” when preceding a list of elements, modify the entire list of elements and do not modify the individual elements of the list. For example, “at least one of X, Y, and Z,” “at least one of X, Y, or Z,” “at least one selected from the group consisting of X, Y, and Z,” and “at least one selected from the group consisting of X, Y, or Z” may be construed as X only, Y only, Z only, any combination of two or more of X, Y, and Z, such as, for instance, XYZ, XY, YZ, and XZ, or any variation thereof. Similarly, the expressions “at least one of A and B” and “at least one of A or B” may include A, B, or A and B. As used herein, “or” generally means “and/or,” and the term “and/or” includes any and all combinations of one or more of the associated listed items. For example, the expression “A and/or B” may include A, B, or A and B. Similarly, expressions such as “at least one of,” “a plurality of,” “one of,” and other prepositional phrases, when preceding a list of elements, modify the entire list of elements and do not modify the individual elements of the list. When “C to D” is stated, it means C or more and D or less, unless otherwise specified.

It will be understood that, although the terms “first,” “second,” “third,” etc., may be used herein to describe various elements, components, regions, layers and/or sections, these elements, components, regions, layers and/or sections should not be limited by these terms. These terms do not correspond to a particular order, position, or superiority, and are only used to distinguish one element, member, component, region, area, layer, section, or portion from another element, member, component, region, area, layer, section, or portion. Thus, a first element, component, region, layer, or section described below could be termed a second element, component, region, layer, or section, without departing from the spirit and scope of the present disclosure. The description of an element as a “first” element may not require or imply the presence of a second element or other elements. The terms “first,” “second,” etc. may also be used herein to differentiate different categories or sets of elements. For conciseness, the terms “first,” “second,” etc. may represent “first-category (or first-set),” “second-category (or second-set),” etc., respectively.

In the examples, the x-axis, the y-axis, and/or the z-axis are not limited to three axes of a rectangular coordinate system, and may be interpreted in a broader sense. For example, the x-axis, the y-axis, and the z-axis may be perpendicular to one another, or may represent different directions that are not perpendicular to one another. The same applies for first, second, and/or third directions.

The terminology used herein is for the purpose of describing embodiments only and is not intended to be limiting of the present disclosure. As used herein, the singular forms “a” and “an” are intended to include the plural forms as well, while the plural forms are also intended to include the singular forms, unless the context clearly indicates otherwise. It will be further understood that the terms “comprises,” “comprising,” “have,” “having,” “includes,” and “including,” when used in this specification, specify the presence of the stated features, integers, steps, operations, elements, and/or components, but do not preclude the presence or addition of one or more other features, integers, steps, operations, elements, components, and/or groups thereof.

When one or more embodiments may be implemented differently, a specific process order may be performed differently from the described order. For example, two consecutively described processes may be performed substantially at the same time or performed in an order opposite to the described order.

As used herein, the terms “substantially,” “about,” “approximately,” and similar terms are used as terms of approximation and not as terms of degree, and are intended to account for the inherent deviations in measured or calculated values that would be recognized by those of ordinary skill in the art. For example, “substantially” may include a range of +/−5% of a corresponding value. “About” or “approximately,” as used herein, is inclusive of the stated value and means within an acceptable range of deviation for the particular value as determined by one of ordinary skill in the art, considering the measurement in question and the error associated with measurement of the particular quantity (i.e., the limitations of the measurement system). For example, “about” may mean within one or more standard deviations, or within +30%, 20%, 10%, 5% of the stated value. Further, the use of “may” when describing embodiments of the present disclosure refers to “one or more embodiments of the present disclosure.” Furthermore, the expression “being the same” may mean “being substantially the same”. In other words, the expression “being the same” may include a range that can be tolerated by those of ordinary skill in the art. The other expressions may also be expressions from which “substantially” has been omitted.

In some embodiments well-known structures and devices may be described in the accompanying drawings in relation to one or more functional blocks (e.g., block diagrams), units, and/or modules to avoid unnecessarily obscuring various embodiments. Those skilled in the art will understand that such block, unit, and/or module are/is physically implemented by a logic circuit, an individual component, a microprocessor, a hard wire circuit, a memory element, a line connection, and other electronic circuits. This may be formed using a semiconductor-based manufacturing technique or other manufacturing techniques. The block, unit, and/or module implemented by a microprocessor or other similar hardware may be programmed and controlled using software to perform various functions discussed herein, optionally may be driven by firmware and/or software. In addition, each block, unit, and/or module may be implemented by dedicated hardware, or a combination of dedicated hardware that performs some functions and a processor (for example, one or more programmed microprocessors and related circuits) that performs a function different from those of the dedicated hardware. In addition, in some embodiments, the block, unit, and/or module may be physically separated into two or more interact individual blocks, units, and/or modules without departing from the scope of the present disclosure. In addition, in some embodiments, the block, unit and/or module may be physically combined into more complex blocks, units, and/or modules without departing from the scope of the present disclosure.

Unless otherwise defined, all terms (including technical and scientific terms) used herein have the same meaning as commonly understood by one of ordinary skill in the art to which the present disclosure belongs. It will be further understood that terms, such as those defined in commonly used dictionaries, should be interpreted as having a meaning that is consistent with their meaning in the context of the relevant art and/or the present specification, and should not be interpreted in an idealized or overly formal sense, unless expressly so defined herein.

Hereinafter, in the specification, a “thickness” refers to a value that is measured in a third direction DR3. A “width” may refer to a value measured in a first direction DR1 or a second direction DR2 that is a horizontal direction.

Hereinafter, embodiments of the present disclosure will be described with reference to the drawings.

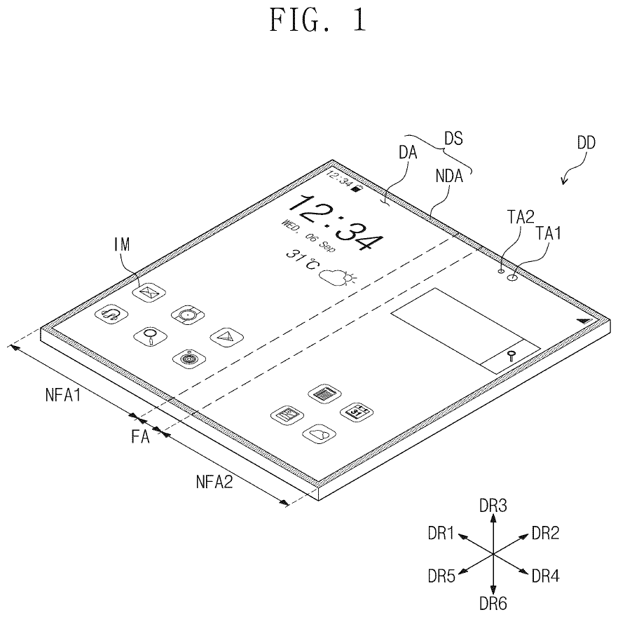

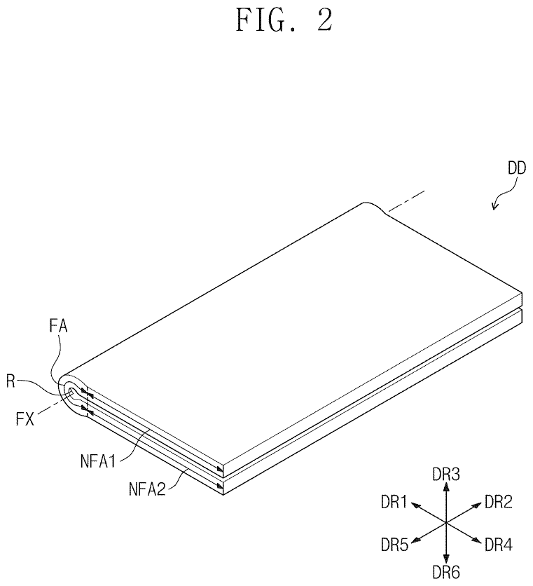

FIG. 1 is a perspective view of a display device according to one or more embodiments of the present disclosure. FIG. 2 is a view illustrating a folding state of the display device illustrated in FIG. 1.

Referring to FIG. 1, a display device DD according to one or more embodiments of the present disclosure may have a rectangular shape having long sides that extend in one direction, and short sides that extend in another direction that crosses the one direction. However, the present disclosure is not limited thereto, and the display device DD may have various shapes, such as a circle and a polygon. The display device DD may be a flexible display device.

Hereinafter, a direction that substantially perpendicularly crosses a plane that is defined by the first direction DR1 and the second direction DR2 is defined as the third direction DR3. Furthermore, in the present specification, “when viewed on a plane” may be defined as a state of being viewed from the third direction DR3. Furthermore, an opposite direction to the first direction DR1 is defined as a fourth direction DR4, an opposite direction to the second direction DR2 is defined as a fifth direction DR5, and an opposite direction to the third direction DR3 is defined as a sixth direction DR6.

The display device DD may include a folding area FA and a plurality of non-folding areas NFA1 and NFA2. The non-folding areas NFA1 and NFA2 may include a first non-folding area NFA1 and a second non-folding area NFA2. The folding area FA may be located between the first non-folding area NFA1 and the second non-folding area NFA2. The first non-folding area NFA1, the folding area FA, and the second non-folding area NFA2 may be arranged in the first direction DR1.

For example, one folding area FA and two non-folding areas NFA1 and NFA2 are illustrated, but the numbers of the folding areas FA and the non-folding areas NFA1 and NFA2 are not limited thereto. For example, the display device DD may include two or more non-folding areas and a plurality of folding areas that are located between the non-folding areas.

An upper surface of the display device DD may be defined as a display surface DS, and the display surface DS may have a plane that is defined by a first direction DR1 and a second direction DR2. Images IM that are generated by the display device DD may be provided to a user through the display surface DS.

The display surface DS may include a display area DA, and a non-display area NDA around the display area DA. The display area DA may display an image, and the non-display area NDA may not display an image. The non-display area NDA may surround the display area DA (e.g., in plan view), and may define a periphery of the display device DD, which is printed in a corresponding color.

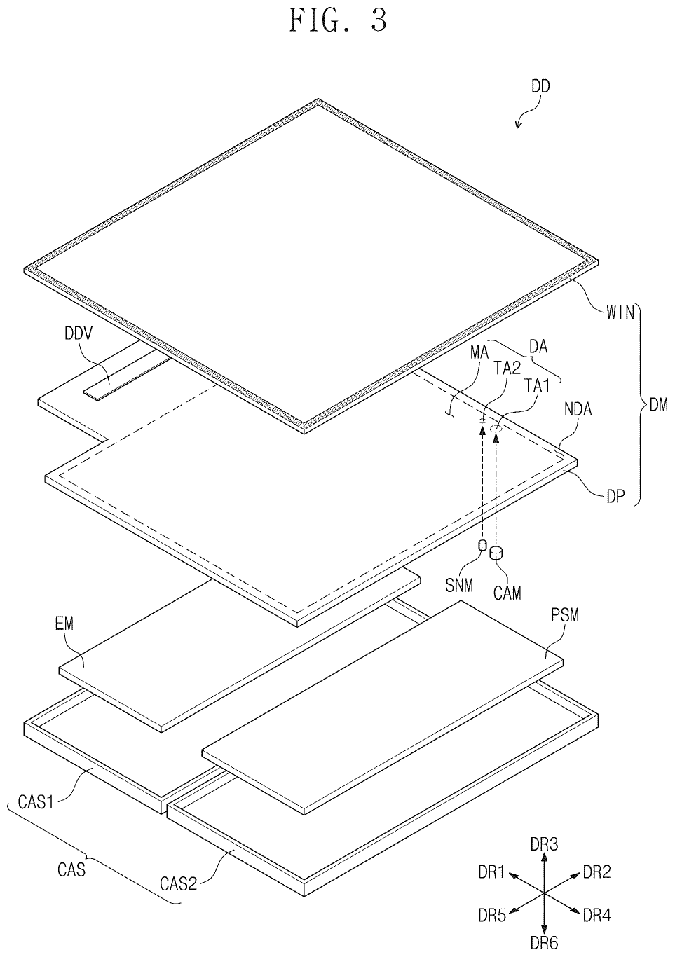

In one or more embodiments of the present disclosure, component areas TA1 and TA2 may be areas that are defined on a display panel DP (see FIG. 3) that will be described below, and may be areas that overlap, for example, a camera module CAM and a sensor module SNM. The component areas TA1 and TA2 may be adjacent to the periphery of the display device DD. The component areas TA1 and TA2 may be located in the display area DA that is adjacent to the non-display area NDA. The component areas TA1 and TA2 may be located in the second non-folding area NFA2, but are not limited thereto, and may be located in the first non-folding area NFA1.

Referring to FIG. 2, the display device DD may be a foldable display device DD that is folded or unfolded. For example, the folding area FA is curved with respect to a folding axis FX that is parallel to the second direction DR2, so that the display device DD may be folded. The folding axis FX may be defined as a long axis that is parallel to the long sides of the display device DD. However, the present disclosure is not limited thereto, and the folding axis FX is defined as a short axis that is parallel to the short sides, and the display device DD may be folded around the folding axis FX that is parallel to the short sides.

When the display device DD is folded, the first non-folding area NFA1 and the second non-folding area NFA2 may face each other, and the display device DD may be in-folded so that the display surface DS is not exposed to the outside. However, one or more embodiments of the present disclosure is not limited thereto. For example, the display device DD may be out-folded around the folding axis FX so that the display surface DS is exposed to the outside.

A distance between the first non-folding area NFA1 and the second non-folding area NFA2 may be less than a diameter of a circle that is defined by a radius “R” of curvature of the folding area FA. In this case, the folding area FA is folded in a dumbbell shape, and the distance between the first non-folding area NFA1 and the second non-folding area NFA2 may become smaller.

FIG. 3 is an exploded perspective view of the display device illustrated in FIG. 1.

Referring to FIG. 3, the display device DD may include a display module DM, a camera module CAM, a sensor module SNM, an electronic module EM, a power module PSM, and a case CAS.

The display module DM may include a window WIN and a display panel DP. By way of example, a window WIN and a display panel DP in a stack structure of the display module DM are illustrated in FIG. 3, but the display module DM may further include various components, in addition to the window WIN and the display panel DP. A detailed stack structure of the display module DM will be described in detail below.

The window WIN may provide a front surface of the display device DD. The window WIN may transmit an image that is generated by the display panel DP to provide the image to a user.

The display panel DP may include a display area DA (refer to FIG. 1) of the display device DD and a display area DA corresponding to a non-display area NDA (refer to FIG. 1), and the non-display area NDA (refer to FIG. 1). In the specification, “an area/part and an area/part correspond to each other” means overlapping, and may not be limited to the same area.

A main display area MA and component areas TA1 and TA2 may be defined on the display panel DP. The display area DA may include the main display area MA and the component areas TA1 and TA2. The component areas TA1 and TA2 have a light transmittance that is higher than that of the main display area MA. The camera module CAM may be located under the first component area TA1, and a sensor module SNM may be located under the second component area TA2. Light that passes through the component areas TA1 and TA2 may be provided to the camera module CAM and the sensor module SNM. For example, the sensor module SNM may include a proximity light sensor, but the type of sensor is not limited thereto. The camera module CAM may include a camera that may photograph an external image. A plurality of sensor modules SNM and a plurality of camera modules CAM may be provided, respectively.

The display module DM may include a data driver DDV that is located on the non-display area NDA of the display panel DP. The data driver DDV may be manufactured in the form of an integrated circuit chip, and may be mounted on the non-display area NDA. However, the present disclosure is not limited thereto, and the data driver DDV may be mounted on a flexible circuit board that is connected to the display panel DP.

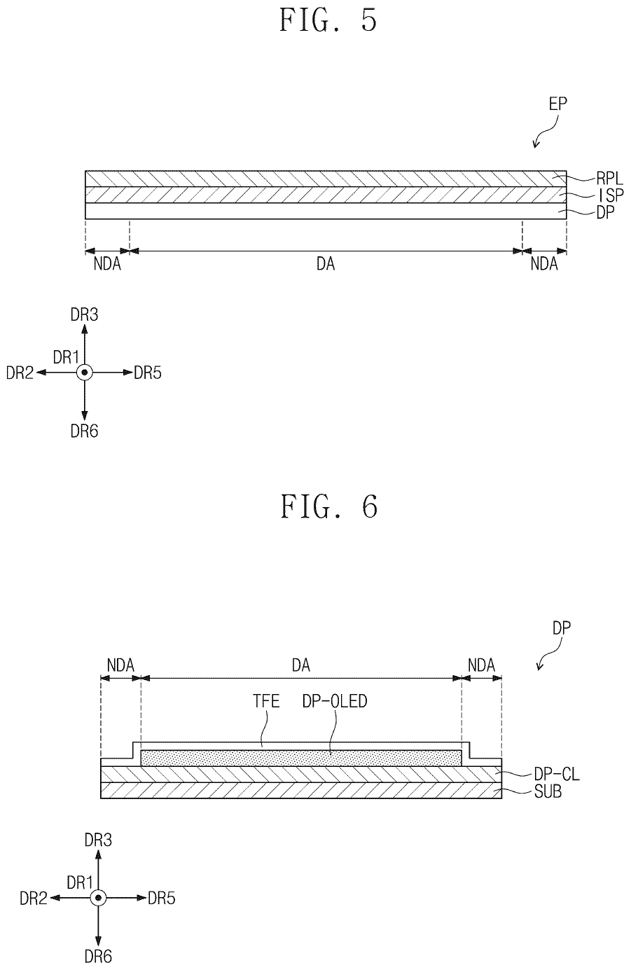

In one or more embodiments, the display module DM may further include an input-sensing part ISP (see FIG. 5) and an anti-reflection layer RPL (see FIG. 5). The electronic panel EP (see FIG. 5) including the display panel DP, the input-sensing part ISP (see FIG. 5), and the anti-reflection layer RPL (see FIG. 5) will be described in detail with reference to FIG. 5.

The electronic module EM and the power module PSM may be located under the display panel DP. In one or more embodiments, the electronic module EM and the power module PSM may be connected to each other through a separate flexible circuit board. The electronic module EM may control the operation of the display module DM. The power module PSM may supply electric power to the electronic module EM.

The case CAS may accommodate the display module DM, the electronic module EM, and the power module PSM. The case CAS may include two first cases CAS1 and second cases CAS2 to fold the display module DM. The first and second cases CAS1 and CAS2 may extend in the second direction DR2 and may be located in the first direction DR1.

In one or more embodiments, the display device DD may further include a hinge structure for connecting the first and second cases CAS1 and CAS2 and for rotating the first and second cases CAS1 and CAS2 so that the display device DD is folded. The case CAS may protect the display module DM, the electronic module EM, and the power module PSM.

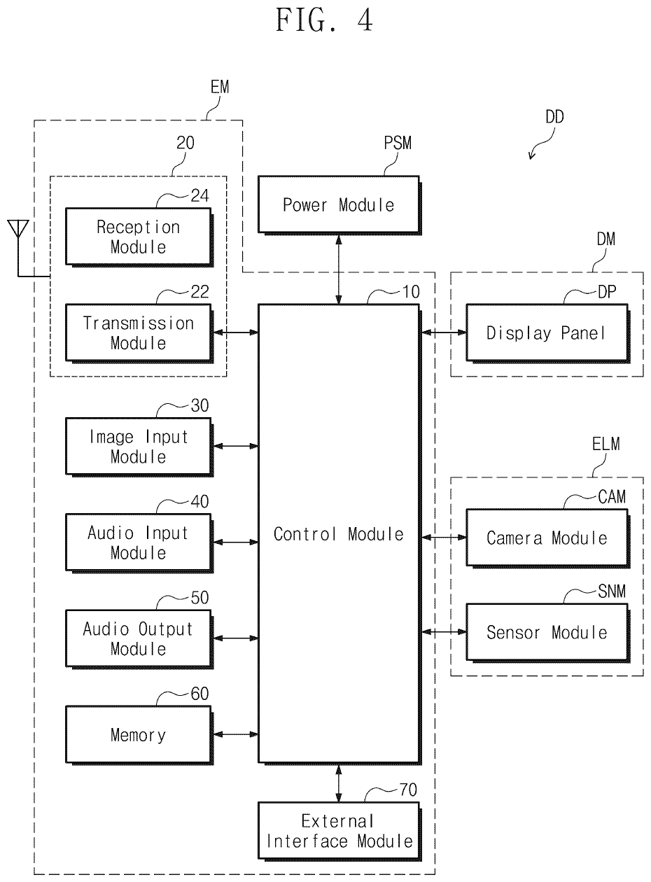

FIG. 4 is a block diagram of the display device illustrated in FIG. 3.

Referring to FIG. 4, the display device DD may include an electronic module EM, a power module PSM, a display module DM, and an electro-optical module ELM. The electronic module EM may include a control module 10, a wireless communication module 20, an image input module 30, an audio input module 40, an audio output module 50, a memory 60, and an external interface module 70. The modules may be mounted on a circuit board, or may be electrically connected to each other through a flexible circuit board. The electronic module EM may be electrically connected to the power module PSM.

The control module 10 may control the overall operation of the display device DD. For example, the control module 10 may activate or deactivate the display module DM according to a user input. The control module 10 may control the image input module 30, the audio input module 40, and the audio output module 50 according to a user input. The control module 10 may include at least one microprocessor.

The wireless communication module 20 may transmit/receive a wireless signal to/from other terminals by using Bluetooth® (Bluetooth® being a registered trademark of Bluetooth Sig, Inc., Kirkland, WA) or Wi-Fi® (Wi-Fi® being a registered trademark of the non-profit Wi-Fi Alliance). The wireless communication module 20 may transmit/receive a voice signal by using a general communication line. The wireless communication module 20 may include a transmission circuit 22 for modulating and transmitting a signal, and a reception circuit 24 for demodulating a received signal.

The image input module 30 may process an image signal, and may convert the image signal into image data that may be displayed on the display module DM. The audio input module 40 may receive an external sound signal through a microphone in a recording mode or a voice recognition mode, and may convert the received sound signal into electrical voice data. The audio output module 50 may convert sound data received from the wireless communication module 20 or sound data stored in the memory 60 to output the converted sound data to the outside.

The external interface module 70 may serve as an interface that is connected to an external charger, a wired/wireless data port, and a card socket (e.g., a memory card, a SIM/UIM card).

The power module PSM may supply power that is required for the overall operation of the display device DD. The power module PSM may include a general battery device.

The electro-optical module ELM may be an electronic component that outputs or receives an optical signal. The electro-optical module ELM may transmit or receive an optical signal through a partial area of the display module DM. In one or more embodiments, the electro-optical module ELM may include the camera module CAM and the sensor module SNM.

FIG. 5 is a view illustrating a cross section of an electronic panel including the display panel illustrated in FIG. 3 by way of example. FIG. 6 is a view illustrating a cross section of the display panel illustrated in FIG. 5 by way of example.

By way of example, FIGS. 5 and 6 are illustrated with cross-sections viewed in the first direction DR1.

Referring to FIG. 5, the electronic panel EP may include a display panel DP, an input-sensing part ISP that is located on the display panel DP, and an anti-reflection layer RPL that is located on the input-sensing part ISP. The above-described display module DM may include an electronic panel EP.

The display panel DP may be a flexible display panel. The display panel DP according to one or more embodiments of the present disclosure may be a light-emitting display panel, and is not particularly limited thereto. For example, the display panel DP may be an organic light-emitting display panel or an inorganic light-emitting display panel. A light emission layer of the organic light-emitting display panel may include an organic light-emitting material. A light emission layer of the inorganic light-emitting display panel may include a quantum dot, a quantum rod, and the like. Hereinafter, the display panel DP will be described as an organic light-emitting display panel.

In one or more embodiments, the input-sensing part ISP may include a plurality of sensing parts for sensing an external input in a capacitive manner. When the display device DD is manufactured, the input-sensing part ISP may be manufactured directly on the display panel DP. However, the present disclosure is not limited thereto, and the input-sensing part ISP may be manufactured as a separate panel from the display panel DP, and may be attached to the display panel DP by an adhesive layer.

When the display device DD is manufactured, the anti-reflection layer RPL may be directly manufactured on the input-sensing part ISP. However, the present disclosure is not limited thereto, and the anti-reflection layer RPL is manufactured as a separate panel, and may be attached to the input-sensing part ISP by an adhesive layer.

The anti-reflection layer RPL may be defined as an anti-reflection film of external light. The anti-reflection layer RPL may decrease a reflectance of external light that is input from the display device DD toward the display panel DP.

Referring to FIG. 6, the display panel DP may include a substrate SUB, a circuit element layer DP-CL that is located on the substrate SUB, a display element layer DP-OLED that is located on the circuit element layer DP-CL, and a thin film encapsulation layer TFE that is located on the display element layer DP-OLED.

The substrate SUB may include a display area DA and a non-display area NDA around the display area DA. The substrate SUB may include a flexible plastic material, such as glass or polyimide (PI). The display element layer DP-OLED may be located on the display area DA.

A plurality of pixels may be located on the circuit element layer DP-CL and the display element layer DP-OLED. Each of the pixels may include a transistor that is located on the circuit element layer DP-CL and a light-emitting element that is located on the display element layer DP-OLED and is connected to the transistor.

The thin film encapsulation layer TFE may be located on the circuit element layer DP-CL to cover the display element layer DP-OLED. The thin film encapsulation layer TFE may protect pixels from moisture, oxygen, and external foreign substances.

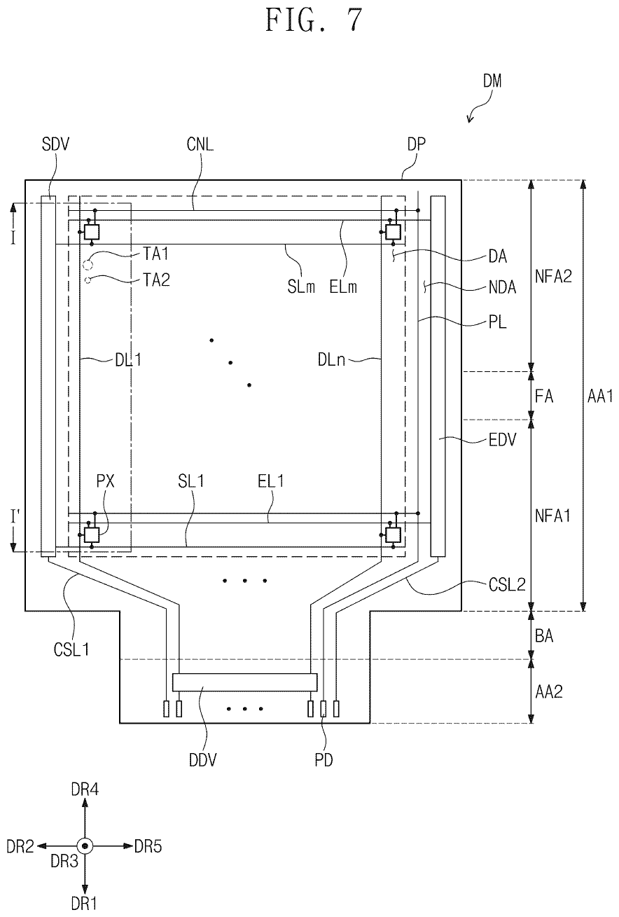

FIG. 7 is a plan view of the display module illustrated in FIG. 3.

Referring to FIG. 7, the display module DM may include a display panel DP, a scan driver SDV, a data driver DDV, and an emission driver EDV.

The display panel DP may include a first area AA1, a second area AA2, and a bending area BA between the first area AA1 and the second area AA2. The bending area BA may extend in the second direction DR2, and the first area AA1, the bending area BA, and the second area AA2 may be arranged in the first direction DR1.

The first area AA1 may include a display area DA and a non-display area NDA around the display area DA. The non-display area NDA may surround the display area DA. The display area DA may be an area that displays an image, and the non-display area NDA may be an area that does not display an image. The second area AA2 and the bending area BA may be areas that do not display an image.

When viewed from the second direction DR2, the first area AA1 may include a first non-folding area NFA1, a second non-folding area NFA2, and a folding area FA between the first non-folding area NFA1 and the second non-folding area NFA2. The first and second non-folding areas NFA1 and NFA2 and the folding area FA may correspond to the first and second non-folding areas NFA1 and NFA2 and the folding area FA of the display device DD illustrated in FIG. 1. The component areas TA1 and TA2 may be defined in the display area DA and the second non-folding area NFA2.

The first area AA1 may be curved and folded with respect to the folding axis FX described above. For example, when the folding area FA of the first area AA1 is folded with respect to the folding axis FX described above, the display panel DP may be folded.

The display panel DP may include a plurality of pixels PX, a plurality of scan lines SL1 to SLm, a plurality of data lines DL1 to DLn, a plurality of light-emitting lines EL1 to ELm, first and second control lines CSL1 and CSL2, a power line PL, a plurality of connection lines CNL, and a plurality of pads PD. “m” and “n” are natural numbers. The pixels PX may be located on the display area DA, and may be connected to the scan lines SL1 to SLm, the data lines DL1 to DLn, and the light-emitting lines EL1 to ELm.

The scan driver SDV and the emission driver EDV may be located in the non-display area NDA. The scan driver SDV and the emission driver EDV may be located in the non-display areas NDA that are adjacent to opposite sides of the first area AA1, which are opposite to each other in the second direction DR2. The data driver DDV may be located in the second area AA2. The data driver DDV may be manufactured in the form of an integrated circuit chip and may be mounted on the second area AA2.

The scan lines SL1 to SLm may extend in the second direction DR2 and may be connected to the scan driver SDV. The data lines DL1 to DLn may extend in the first direction DR1, and may be connected to the data driver DDV through the bending area BA. The data driver DDV may be connected to the pixels PX through data lines DL1 to DLn. The light-emitting lines EL1 to ELm may extend in the second direction DR2 and may be connected to the emission driver EDV.

The power line PL may extend in the first direction DR1 and may be located in the non-display area NDA. The power line PL may be located between the display area DA and the emission driver EDV. The power line PL may extend to the second area AA2 through the bending area BA. When viewed in a plan view, the power line PL may extend toward a lower end of the second area AA2. The power line PL may receive a driving voltage.

The connection lines CNL may extend in the second direction DR2 and may be arranged in the first direction DR1. The connection lines CNL may be connected to the power line PL and the pixels PX. A driving voltage may be applied to the pixels PX through the power line PL and the connection lines CNL that are connected to each other.

The first control line CSL1 may be connected to the scan driver SDV, and may extend toward a lower end of the second area AA2 through the bending area BA. The second control line CSL2 may be connected to the emission driver EDV, and may extend toward a lower end of the second area AA2 through the bending area BA. The data driver DDV may be located between the first control line CSL1 and the second control line CSL2.

When viewed in a plane, the pads PD may be located adjacent to a lower end of the second area AA2. The data driver DDV, the power line PL, the first control line CSL1, and the second control line CSL2 may be connected to the pads PD.

The data lines DL1 to DLn may be connected to corresponding pads PD through a data driver DDV. For example, the data lines DL1 to DLn may be connected to the data driver DDV, and the data driver DDV may be connected to pads PD corresponding to the data lines DL1 to DLn, respectively.

In one or more embodiments, a printed circuit board may be connected to the pads PD, and a timing controller and a voltage generator may be located on the printed circuit board. The timing controller may be manufactured from an integrated circuit chip and may be mounted on the printed circuit board. The timing controller and the voltage generator may be connected to the pads PD through a printed circuit board.

The timing controller may control operations of the scan driver SDV, the data driver DDV, and the emission driver EDV. The timing controller may generate a scan control signal, a data control signal, and a light emission control signal in response to control signals received from the outside. The voltage generator may generate a driving voltage.

The scan control signal may be provided to the scan driver SDV through a first control line CSL1. The emission control signal may be provided to the emission driver EDV through a second control line CSL2. The data control signal may be provided to the data driver DDV. The timing controller may receive image signals from the outside, and may convert a data format of the image signals according to an interface specification with the data driver DDV to provide the converted data format to the data driver DDV.

The scan driver SDV may generate a plurality of scan signals in response to a scan control signal. The scan signals may be applied to the pixels PX through the scan lines SL1 to SLm. The scan signals may be sequentially applied to the pixels PX.

The data driver DDV may generate a plurality of data voltages corresponding to image signals in response to a data control signal. The data voltages may be applied to the pixels PX through data lines DL1 to DLn. The emission driver EDV may generate a plurality of light emission signals in response to a light emission control signal. The light emission signals may be applied to the pixels PX through light-emitting lines EL1 to ELm.

The pixels PX may receive data voltages in response to scan signals. The pixels PX may display an image by emitting light having a luminance corresponding to the data voltages in response to light emission signals. The emission time of the pixels PX may be controlled by light emission signals.

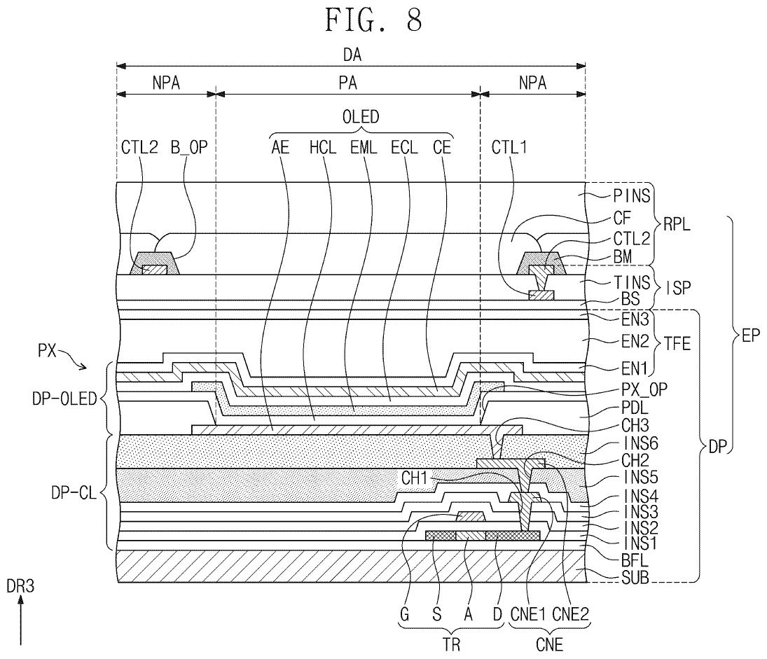

FIG. 8 is a view illustrating a cross section of an electronic panel corresponding to any one pixel illustrated in FIG. 7 by way of example.

Referring to FIG. 8, the display panel DP may include a pixel PX, and the pixel PX may include a transistor TR and a light-emitting element OLED. The light-emitting element OLED may include a first electrode AE (or an anode), a second electrode CE (or a cathode), a hole control layer HCL, an electronic control layer ECL, and a light emission layer EML.

The transistor TR and the light-emitting element OLED may be located on the substrate SUB. Although one transistor TR is illustrated by way of example, substantially, the pixel PX may include a plurality of transistors and at least one capacitor for driving the light-emitting element OLED.

The display area DA may include a light-emitting area PA corresponding to each of the pixels PX, and a non-light-emitting area NPA around the light-emitting area PA. The light-emitting element OLED may be located in the light-emitting area PA.

A buffer layer BFL may be located on the substrate SUB, and the buffer layer BFL may be an inorganic layer. A semiconductor pattern may be located on the buffer layer BFL. The semiconductor pattern may include polysilicon, amorphous silicon, or metal oxide.

The semiconductor pattern may be doped with an N-type dopant or a P-type dopant. The semiconductor pattern may include a high-doped area and a low-doped area. A conductivity of the high-doped area is greater than that of the low-doped area, and may substantially serve as a source electrode and a drain electrode of the transistor TR. The low-doped area may substantially correspond to an active (or channel) of the transistor.

A source “S”, an active “A”, and a drain “D” of the transistor TR may be formed from a semiconductor pattern. A first insulating layer INS1 may be located on the semiconductor pattern. A gate “G” of the transistor TR may be located on the first insulating layer INS1. A second insulating layer INS2 may be located on the gate “G”. A third insulating layer INS3 may be located on the second insulating layer INS2.

A connection electrode CNE may include a first connection electrode CNE1 and a second connection electrode CNE2 to connect the transistor TR and the light-emitting element OLED. The first connection electrode CNE1 may be located on the third insulating layer INS3, and may be connected to the drain “D” through a first contact hole CH1 defined in the first to third insulating layers INS1 to INS3.

The fourth insulating layer INS4 may be located on the first connection electrode CNE1. The fifth insulating layer INS5 may be located on the fourth insulating layer INS4. The second connection electrode CNE2 may be located on the fifth insulating layer INS5. The second connection electrode CNE2 may be connected to the first connection electrode CNE1 through second contact holes CH2 defined in the fourth and fifth insulating layers INS4 and INS5.

A sixth insulating layer INS6 may be located on the second connection electrode CNE2. The layers of the buffer layer BFL to the sixth insulating layer INS6 may be defined as the circuit element layer DP-CL. The first to sixth insulating layers INS1 to INS6 may be inorganic layers or organic layers.

A first electrode AE may be located on the sixth insulating layer INS6. The first electrode AE may be connected to the second connection electrode CNE2 through a third contact hole CH3 defined in the sixth insulating layer INS6. A pixel definition layer PDL, in which an opening PX_OP for exposing a corresponding portion of the first electrode AE is defined, may be located on the first electrode AE and the sixth insulating layer INS6.

The hole control layer HCL may be located on the first electrode AE and the pixel definition layer PDL. The hole control layer HCL may include a hole transport layer and a hole injection layer.

The light emission layer EML may be located on the hole control layer HCL. The light emission layer EML may be located in an area corresponding to the opening PX_OP. The light emission layer EML may include an organic material and/or an inorganic material. The light emission layer EML may generate any one of red, green, or blue light.

An electron control layer ECL may be located on the light emission layer EML and the hole control layer HCL. The electron control layer ECL may include an electron transport layer and an electron injection layer. The hole control layer HCL and the electron control layer ECL may be located in common in the light-emitting area PA and the non-light-emitting area NPA.

The second electrode CE may be located on the electronic control layer ECL. The second electrode CE may be located in common on the pixels PX. The layer, on which the light-emitting element OLED is located, may be defined as a display element layer DP-OLED.

A thin film encapsulation layer TFE may be located on the second electrode CE to cover the pixel PX. The thin film encapsulation layer TFE may include a first encapsulation layer EN1 that is located on the second electrode CE, a second encapsulation layer EN2 that is located on the first encapsulation layer EN1, and a third encapsulation layer EN3 that is located on the second encapsulation layer EN2.

The first and third encapsulation layers EN1 and EN3 may include an inorganic insulating layer, and may protect the pixel PX from moisture/oxygen. The second encapsulation layer EN2 may include an organic insulating layer, and may protect the pixel PX from foreign substances, such as dust particles.

A first voltage may be applied to the first electrode AE through the transistor TR, and a second voltage having a level that is lower than that of the first voltage may be applied to the second electrode CE. Holes and electrons that are injected into the light emission layer EML are combined to form excitons, and the light-emitting element OLED may emit light while the excitons are transitioned to a ground state.

The layers from the substrate SUB to the thin film encapsulation layer TFE may be defined as the display panel DP. An input-sensing part ISP may be located on the thin film encapsulation layer TFE. The input-sensing part ISP may be directly manufactured on the upper surface of the thin film encapsulation layer TFE.

A base layer BS of the input-sensing part ISP may be located on the thin film encapsulation layer TFE. The base layer BS may include an inorganic insulating layer. At least one inorganic insulating layer may be provided on the thin film encapsulation layer TFE as the base layer BS.

The input-sensing part ISP may include a first conductive pattern CTL1, and a second conductive pattern CTL2 that is located on the first conductive pattern CTL1. The first conductive pattern CTL1 may be located on the base layer BS. An insulating layer TINS may be located on the base layer BS to cover the first conductive pattern CTL1. The insulating layer TINS may include an inorganic insulating layer or an organic insulating layer. The second conductive pattern CTL2 may be located on the insulating layer TINS.

The first and second conductive patterns CTL1 and CTL2 may overlap the non-light-emitting area NPA. In one or more embodiments, the first and second conductive patterns CTL1 and CTL2 may be located on the non-light-emitting area NPA between the light-emitting areas PA, and may have a mesh shape.

The first and second conductive patterns CTL1 and CTL2 may form sensors of the input-sensing part ISP described above. For example, the first and second conductive patterns CTL1 and CTL2 of the mesh shape may be separated from each other in a corresponding area to form sensors. A portion of the second conductive pattern CTL2 may be connected to the first conductive pattern CTL1.

An anti-reflection layer RPL may be located on the second conductive pattern CTL2. The anti-reflection layer RPL may include a black matrix BM and a plurality of color filters CF. The black matrix BM may overlap the non-light-emitting area NPA, and the color filters CF may overlap the light-emitting areas PA, respectively.

The black matrix BM may be located on the insulating layer TINS to cover the second conductive pattern CTL2. In the black matrix BM, the light-emitting area PA and an opening B_OP that overlaps the opening PX_OP may be defined. The black matrix BM may absorb and shield light. A width of the opening B_OP may be greater than a width of the opening PX_OP.

The color filters CFs may be located on the first insulating layer TINS and the black matrix BM. The color filters CFs may be located in an openings B_OP, respectively. A planarization insulating layer PINS may be located on the color filters CF. The planarization insulating layer PINS may provide a flat upper surface.

When the external light that travels toward the display panel DP is reflected from the display panel DP and provided to an external user again, the user may visually recognize the external light, like a mirror. To reduce or prevent the effect of this phenomenon, by way of example, the anti-reflection layer RPL may include color filters CFs that display the same color as that of the pixels PX of the display panel DP. The color filters CFs may filter the external light to the same colors as that of the pixels PX. In this case, the external light may not be visually recognized by the user.

However, one or more embodiments of the present disclosure is not limited thereto, and the anti-reflection layer RPL may include a polarizing film to decrease a reflectance of the external light. The polarizing film may be separately manufactured and may be attached to the input-sensing part ISP by an adhesive layer. The polarizing film may include a retarder and/or a polarizer.

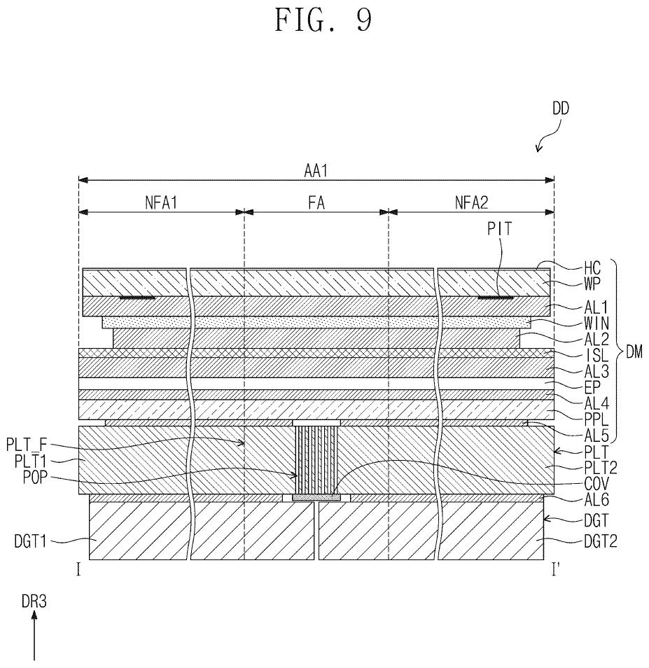

FIG. 9 is a cross-sectional view taken along the line I-I′ illustrated in FIG. 7.

By way of example, FIG. 9 illustrates a cross-section of the display device DD taken along the line I-I′, the display module DM, a support plate PLT, a sixth adhesive layer AL6, and a digitizer DGT.

Referring to FIG. 9, the display device DD may include a display module DM, a support plate PLT, and a digitizer DGT. The display module DM may include a hard coating layer HC, a printed layer PIT, a window WIN, a window protective layer WP, an impact-absorbing layer ISL, an electronic panel EP, and a panel protective layer PPL. The display device DD may include first to sixth adhesive layers AL1 to AL6 for combining the components with each other.

The display module DM may be a flexible display module. The display module DM may include a first non-folding area NFA1, a folding area FA, and a second non-folding area NFA2. The display module DM may be folded as the folding area FA is folded around the above-described folding axis FX.

The window WIN may be located on the impact-absorbing layer ISL. The window WIN may protect the electronic panel EP from external scratches. The window WIN may have optically transparent properties. The window WIN may include glass. However, the present disclosure is not limited thereto, and the window WIN may include a synthetic resin film.

The window WIN may have a multi-layered structure or a single-layered structure. For example, the window WIN may include a plurality of synthetic resin films that are coupled to each other with an adhesive, or may include a glass substrate and a synthetic resin film that are coupled to each other by an adhesive.

The window protective layer WP may be located on the window WIN. The window protective layer WP may include a flexible plastic material, such as polyimide or polyethylene terephthalate. The hard coating layer HC may be located on an upper surface of the window protective layer WP.

The printed layer PIT may be located on a lower surface of the window protective layer WP. The printed layer PIT may have black color, but the color of the printed layer PIT is not limited thereto. The printed layer PIT may be adjacent to a periphery of the window protective layer WP.

The impact-absorbing layer ISL may be located on the electronic panel EP. The impact-absorbing layer ISL may absorb an external impact applied from above the display device DD toward the electronic panel EP to protect the electronic panel EP. The impact-absorbing layer ISL may be manufactured in the form of a stretched film.

The impact-absorbing layer ISL may include a flexible plastic material. The flexible plastic material may be defined as a synthetic resin film. For example, the impact-absorbing layer ISL may include a flexible plastic material, such as polyimide (PI) or polyethylene terephthalate (PET).

The panel protective layer PPL may be located under the electronic panel EP. The panel protective layer PPL may be located under the electronic panel EP. The panel protective layer PPL may protect a lower portion of the electronic panel EP. The panel protective layer PPL may include a flexible plastic material. For example, the panel protective layer PPL may include polyethylene terephthalate (PET).

A first adhesive layer AL1 may be located between the window protective layer WP and the window WIN. The window protective layer WP and the window WIN may be combined with each other by the first adhesive layer AL1. The first adhesive layer AL1 may cover the printed layer PIT.

A second adhesive layer AL2 may be located between the window WIN and the impact-absorbing layer ISL. The window WIN and the impact-absorbing layer ISL may be combined with each other by the second adhesive layer AL2.

A third adhesive layer AL3 may be located between the impact-absorbing layer ISL and the electronic panel EP. The impact-absorbing layer ISL and the electronic panel EP may be combined with each other by the third adhesive layer AL3.

A fourth adhesive layer AL4 may be located between the electronic panel EP and the panel protective layer PPL. The electronic panel EP and the panel protective layer PPL may be combined with each other by the fourth adhesive layer AL4. A fifth adhesive layer AL5 may be located under the panel protective layer PPL.

The support plate PLT may be located under the display module DM to support the display module DM. The support plate PLT may include a non-metallic material. For example, the support plate PLT may include a reinforced fiber composite. The reinforced fiber composite may be a carbon fiber reinforced plastic (CFRP) or a glass fiber reinforced plastic (GFRP).

The support plate PLT may be lightened by including a reinforced fiber composite. The support plate PLT according to one or more embodiments may have a level of modulus and strength that are similar to those of the metal support plate while having a light weight compared to the metal support plate using a metal material by including a reinforced fiber composite.

Because the support plate PLT includes a reinforced fiber composite, a shape of the support plate PLT may be suitably processed compared to the metal support plate. For example, the support plate PLT including the reinforced fiber composite material may be more suitably processed through a laser process or a microblast process.

A plurality of openings POP may be defined at a portion of the support plate PLT that overlaps the folding area FA. The openings POP may be formed while passing through portions of the support plate PLT in the third direction DR3. The openings POP may be formed through the above-described laser process or microblast process.

The support plate PLT may include a first support plate PLT1, a second support plate PLT2, and a folding part PLT_F. By way of example, boundaries between the first support plate PLT1, the second support plate PLT2, and the folding part PLT_F are indicated by a dotted line on the support plate PLT.

The folding part PLT_F may be located between the first support plate PLT1 and the second support plate PLT2. The first support plate PLT1, the folding part PLT_F, and the second support plate PLT2 may be arranged in the first direction DR1. The openings POP may be defined in the folding part PLT_F.

Hereinafter, in the specification, “overlapping” is defined as parts of configurations that overlap each other when viewed on a plane, or in plan view, in a display device that is located flat.

The first support plate PLT1 may be located under the first non-folding area NFA1, and may overlap the first non-folding area NFA1. The second support plate PLT2 may be located under the second non-folding area NFA2, and may overlap the second non-folding area NFA2. The folding part PLT_F may be located under the folding area FA, and may overlap the folding area FA.

A cover layer COV may be located under the support plate PLT. The cover layer COV may cover the openings POP defined in the support plate PLT, under the support plate PLT.

The cover layer COV may have a modulus of elasticity that is lower than that of the support plate PLT. For example, the cover layer COV may include thermoplastic polyurethane or rubber, but a material of the cover layer COV is not limited thereto. The cover layer COV may be manufactured in a sheet shape, and may be attached to the support plate PLT.

The digitizer DGT may be located under the support plate PLT. The cover layer COV may be located between the support plate PLT and the digitizer DGT. The cover layer COV may be spaced apart from an upper surface of the digitizer DGT.

The digitizer DGT is a device that may receive position information indicated by a user on a display surface. The digitizer DGT may be implemented in an electromagnetic resonance scheme. For example, in one or more embodiments, the digitizer DGT may include a digitizer sensor substrate including a plurality of coils. However, the present disclosure is not limited thereto, and the digitizer DGT may be implemented in an active electrostatic manner.

When the user moves a pen on the display device DD, the pen is driven by an AC signal to cause a vibrating magnetic field, and the vibrating magnetic field may induce a signal in the coil. The position of the pen may be detected through a signal induced in the coil. The digitizer DGT may sense an electromagnetic change caused by the approach of the pen and determine the position of the pen.

When the support plate PLT that is located on the digitizer DGT and is adjacent to the digitizer DGT includes metal, a sensitivity of the digitizer DGT may become lower due to the metal. For example, when a signal transmitted on the display device DD is blocked due to signal interference by the metal support plate, the digitizer DGT may not operate normally.

However, in one or more embodiments, the support plate PLT located on the digitizer DGT includes a non-metal reinforced fiber composite, and thus, the digitizer DGT may be operated normally.

The digitizer DGT may be divided into two parts under the folding part PLT_F. The digitizer DGT may include a first digitizer DGT1 and a second digitizer DGT2 that are separated from each other and are located in the first direction DR1. The first digitizer DGT1 may be located under the first support plate PLT1, and the second digitizer DGT2 may be located under the second support plate PLT2.

In one or more embodiments, the first digitizer DGT1 and the second digitizer DGT2 separated from each other may be connected to a digitizer driver through a flexible circuit board.

The first digitizer DGT1 may overlap the first support plate PLT1, and a portion of the folding part PLT_F that is adjacent to the first support plate PLT1. The second digitizer DGT2 may overlap the second support plate PLT2, and a portion of the folding part PLT_F that is adjacent to the second support plate PLT2.

A sixth adhesive layer AL6 may be located between the panel protective layer PPL and the digitizer DGT. The panel protective layer PPL and the digitizer DGT may be combined with each other by the sixth adhesive layer AL6. The sixth adhesive layer AL6 may not be located in an area that overlaps the openings POP. The sixth adhesive layer AL6 may be opened in an area that overlaps the openings POP. In one or more embodiments, a width of the opening of the sixth adhesive layer AL6 in the first direction DR1 may be greater than a width of the opening of the fifth adhesive layer AL5.

The cover layer COV may be located in an area, in which the sixth adhesive layer AL6 is opened. Accordingly, the sixth adhesive layer AL6 may be spaced apart from the cover layer COV without contacting the cover layer COV. A space, in which the cover layer COV is located, may be secured by the opening of the sixth adhesive layer AL6.

The first to sixth adhesive layers AL1 to AL6 may include a transparent adhesive, such as a pressure sensitive adhesive (PSA) or an optically clear adhesive (OCA), but the type of adhesive is not limited thereto.

The electronic panel EP, the impact-absorbing layer ISL, the panel protective layer PPL, and the third and fourth adhesive layers AL3 and AL4 may have the same width. The hard coating layer HC, the window protective layer WP, and the first adhesive layer AL1 may have the same width.

The widths of the electronic panel EP, the impact-absorbing layer ISL, the panel protective layer PPL, and the third and fourth adhesive layers AL3 and AL4 may be greater than the widths of the hard coating layer HC, the window protective layer WP, and the first adhesive layer AL1. Peripheries of the electronic panel EP, the impact-absorbing layer ISL, the panel protective layer PPL, and the third and fourth adhesive layers AL3 and AL4 may be located outside peripheries of the hard coating layer HC, the window protective layer WP, and the first adhesive layer AL1 (e.g., on a plane or in plan view).

The widths of the window WIN and the second adhesive layer AL2 may be less than the widths of the window protective layer WP and the first adhesive layer AL1. The width of the second adhesive layer AL2 may be less than that of the window WIN. The periphery of the window WIN may be located inside the peripheries of the window protective layer WP and the first adhesive layer AL1 (e.g., on a plane/in plan view). The periphery of the second adhesive layer AL2 may be located inside the periphery of the window WIN, while an outer periphery of the fifth adhesive layer AL5 may be located inside the peripheries of the window protective layer WP and the first adhesive layer AL1 (e.g., in plan view).

The width of the support plate PLT may be substantially the same as the width of the electronic panel EP. An outer periphery of the digitizer DGT may overlap an outer periphery of the sixth adhesive layer AL6. Outer peripheries of the digitizer DGT and the sixth adhesive layer AL6 may be located inside an outer periphery of the support plate PLT (e.g., in plan view).

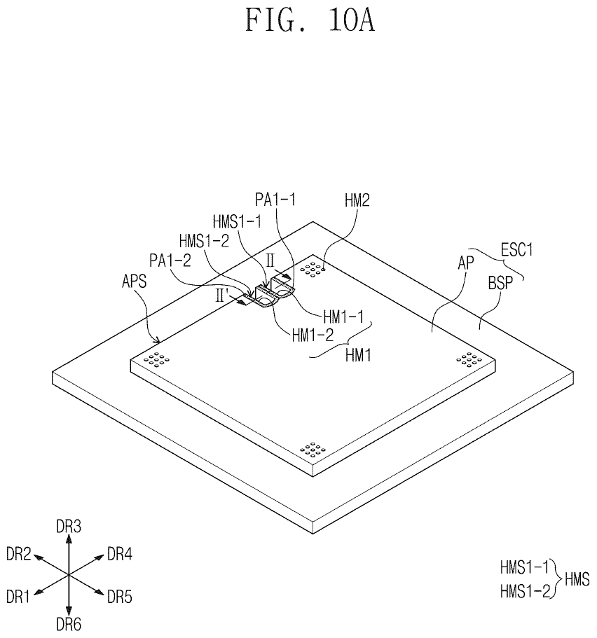

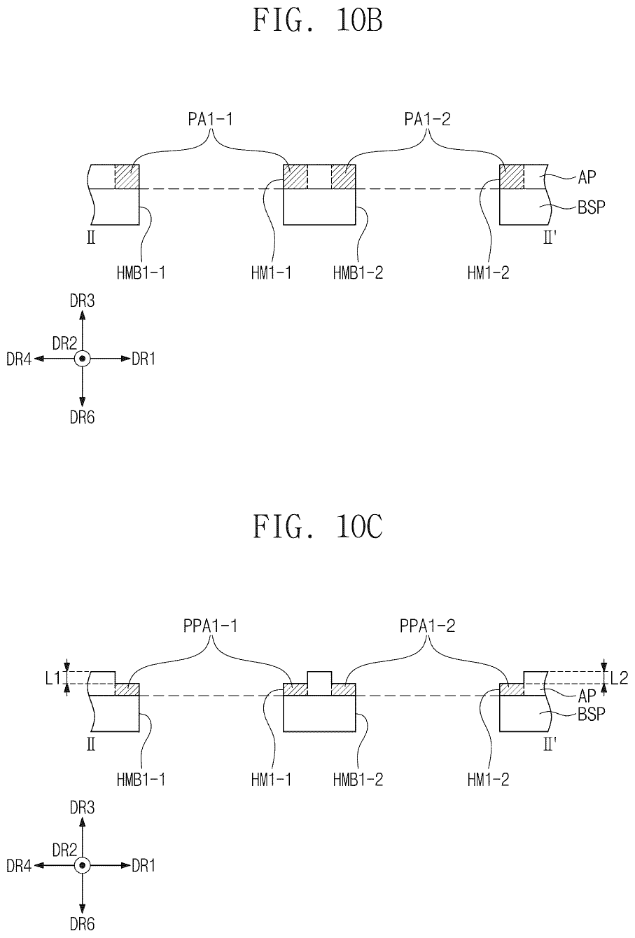

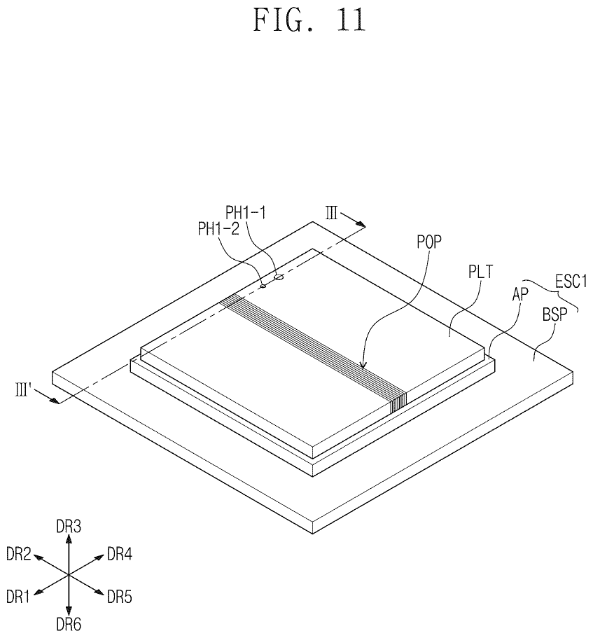

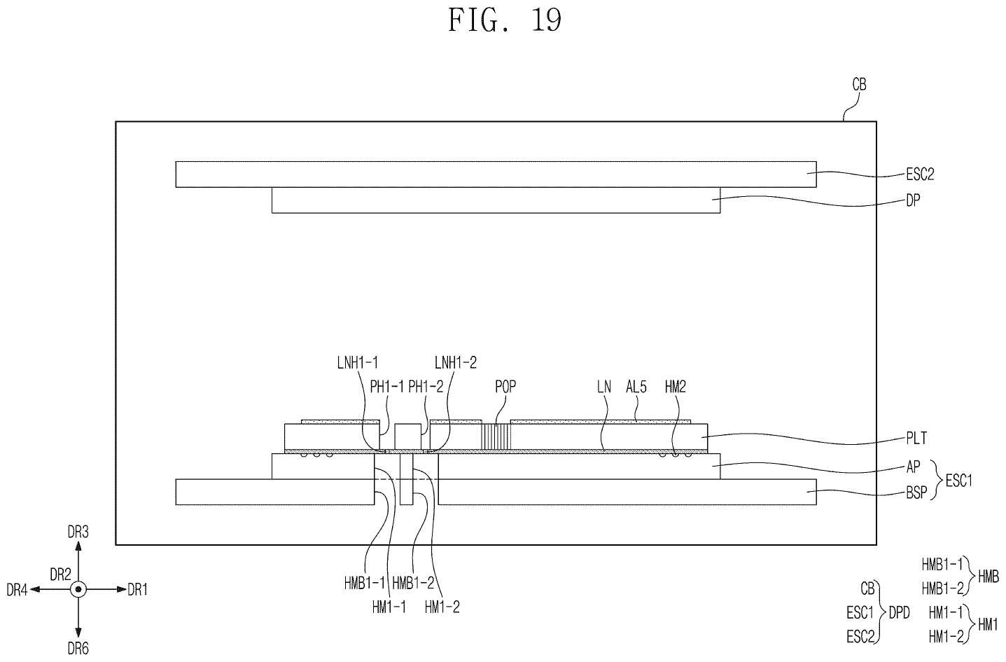

FIG. 10A is a perspective view of a first electrostatic chuck included in a deposition apparatus according to one or more embodiments of the present disclosure. FIGS. 10B and 10C are cross-sectional views taken along the line II-II′ illustrated in FIG. 10A, respectively. A deposition apparatus DPD (see FIG. 19) that will be described later includes a first electrostatic chuck ESC1 and is used for manufacturing the above-described display device DD (see FIG. 1).

Referring to FIG. 10A, the first electrostatic chuck ESC1 includes a suction part AP and a base part BSP. The first electrostatic chuck ESC1 may chuck or de-chuck a target substrate through a pressure using an electrostatic force and a difference in air pressure formed through an electrostatic induction phenomenon.

The first electrostatic chuck ESC1 may chuck the target substrate to proceed with a process of processing the target substrate, and after the target substrate is processed, may repeat a process of de-chucking for processing the next operation.

The first electrostatic chuck ESC1 may chuck the target substrate that is located on the first electrostatic chuck ESC1. However, the present disclosure is not limited thereto, and the target substrate may be chucked in various directions, such as the third direction DR3 or the sixth direction DR6.

The suction part AP is located on the base part BSP, and includes a first recess HM1, and also includes a plurality of second recesses HM2 that are spaced apart from the first recess HM1 on a plane. The suction part AP suctions and fixes a target substrate, for example, a support plate PLT (see FIG. 11) that is located on the suction part AP. The suction part AP may be directly located on the base part BSP. An extent of the suction part AP on a plane (e.g., a profile of the suction part AP in plan view) may be less than that of the base part BSP on the plane.

The suction part AP may include polyimide. The suction part AP may include a coating layer including polyimide. The upper surface of the suction part AP may be an upper surface of a coating layer including polyimide.

The first recess HM1 may include a (1-1)-th recess HM1-1 and a (1-2)-th recess HM1-2. A diameter or width of the first recess HM1 may be larger than a diameter or width of each of a plurality of second recesses HM2. A diameter or width of each of the (1-1)-th recess HM1-1 and the (1-2)-th recess HM1-2 may be larger than a diameter or width of each of a plurality of second recesses HM2.

The first recess HM1 may further include a side recess HMS. The suction part AP may further include a first surface APS that is parallel to the first direction DR1 (e.g., parallel to the first direction DR1 and parallel to the third direction DR3). The side recess HMS may be defined on the first surface APS. For example, the side recess HMS may extend from, or may be partially defined by, the first surface APS. The side recess HMS may overlap the first recess HM1 in the second direction. The side recess HMS may include a first side recess HMS1-1 and a second side recess HMS1-2. The first side recess HMS1-1 may extend from the first surface APS in a direction that is opposite to the second direction DR2 (e.g., in the fifth direction DR5), and may be connected to the (1-1)-th recess HM1-1. The second side recess HMS1-2 may extend from the first surface APS in a direction that is opposite to the second direction DR2 (e.g., in the fifth direction DR5), and may be connected to the (1-2)-th recess HM1-2. The first recess HM1 may be formed by etching at least a portion of the first surface APS.

A plurality of second recesses HM2 defined in the suction part AP may be provided. The second recesses HM2 may be recesses that pass through a portion of the suction part AP. The second recess HM2 overlaps the support plate PLT located on the first electrostatic chuck ESC1 when viewed on a plane. When the first electrostatic chuck ESC1 fixes the support plate PLT by using vacuum, an interior of the second recess HM2 may be maintained in vacuum (e.g., in a vacuum state), and a suction force may be provided so that the support plate PLT is effectively fixed to the first electrostatic chuck ESC1.

The suction part AP may further include a first part PA1-1 that surrounds (e.g., partially surrounds) the (1-1)-th recess HM1-1 on a plane, and a second part PA1-2 that surrounds (e.g., partially surrounds) the (1-2)-th recess HM1-2 on the plane. Each of the first part PA1-1 and the second part PA1-2 may not include polyimide. A detailed description of the first part PA1-1 and the second part PA1-2 will be made in the description of FIGS. 10B and 10C.

FIGS. 10B and 10C are cross-sectional views taken along the line II-II′ illustrated in FIG. 10A, respectively.

Referring to FIG. 10B, a height of the first part PA1-1 and a height of the second part PA1-2 may be the same. The heights of the first part PA1-1 and the second part PA1-2 may be substantially the same as the height of the upper surface of the suction part AP that does not overlap with the first recess HM1, the second recess HM2, the first part PA1-1, and the second part PA1-2.

Referring to FIG. 10C, a height of a first part PPA1-1 and a height of a second part PPA1-2 may be different from a height of the first part PA1-1 and a height of the second part PA1-2 illustrated in FIG. 10B, respectively. Step differences L1 and L2 respectively of upper surfaces of the first part PPA1-1 and the second part PPA1-2 and an upper surface of the suction part AP may be not less than about 1 mm and not more than about 3 mm independently.

FIG. 11 is a perspective view illustrating a state, in which the support plate is fixed on the first electrostatic chuck included in the deposition apparatus according to one or more embodiments of the present disclosure. Referring to FIGS. 10A and 11, in a state, in which the support plate PLT including the pass holes PH1-1 and PH1-2 is located on the first electrostatic chuck ESC1, the first electrostatic chuck ESC1 may fix the support plate PLT by using an electrostatic force and vacuum. The pass holes PH1-1 and PH1-2 of the support plate PLT, which is fixed on the first electrostatic chuck ESC1, and the first recess HM1 overlap each other on a plane. In more detail, the pass holes PH1-1 and PH1-2 of the support plate PLT, when fixed on the first electrostatic chuck ESC1, respectively overlap the (1-1)-th recess HM1-1, and the (1-2)-th recess HM1-2 on a plane. The pass holes PH1-1 and PH1-2 may include a first pass hole PH1-1 and a second pass hole PH1-2. In a state, in which the support plate PLT is combined onto the first electrostatic chuck ESC1, the (1-1)-th recess HM1-1 may overlap the first pass hole PH1-1, and the (1-2)-th recess HM1-2 may overlap the second pass hole PH1-2. A diameter of the (1-1)-th recess HM1-1 may be greater than a diameter of the first pass hole PH1-1. A diameter of the (1-2)-th recess HM1-2 may be greater than a diameter of the second pass hole PH1-2.

When the support plate PLT is de-chucked from the first electrostatic chuck ESC1, there may be a difference between a pressure in interiors of the pass holes PH1-1 and PH1-2 of the support plate PLT and the external pressure when external air is not sufficiently introduced into the pass holes PH1-1 and PH1-2 of the support plate PLT in the process of releasing vacuum with the electrostatic force. Because the process of de-chucking the support plate PLT from the first electrostatic chuck ESC1 is performed after the display panel DP (refer to FIG. 3) is located on the support plate PLT, external air has to be introduced into the pass holes PH1-1 and PH1-2 of the support plate PLT between the first electrostatic chuck ESC1 and the support plate PLT. When external air is not sufficiently introduced into the pass holes PH1-1 and PH1-2 of the support plate PLT during the de-chucking process, the difference between the internal pressures of the pass holes PH1-1 and PH1-2 of the support plate PLT and the external pressure increases. As the difference between the pressure inside the pass holes PH1-1 and PH1-2 of the support plate PLT and the external pressure increases, there may be a defect by which the component areas TA1 and TA2 (see FIG. 3) are recessed in the sixth direction DR6 in the display panel DP (see FIG. 3) located on the support plate PLT.

When de-chucking through the first recess HM1 of the first electrostatic chuck ESC1, a space, in which external air may be smoothly introduced into the pass holes PH1-1 and PH1-2 of the support plate PLT, may be effectively reduced, and thus, a defect by which the component areas TA1 and TA2 (see FIG. 3) are recessed in the display panel DP (see FIG. 3) may be avoided.

Referring to FIGS. 10C and 11, because of the step differences L1 and L2 of upper surfaces the first part PPA1-1 and the second part PPA1-2 with an upper surface of the suction part AP exist, external air may be smoothly introduced into the pass holes PH1-1 and PH1-2 of the support plate PLT between the first electrostatic chuck ESC1 and the support plate PLT in the process of releasing vacuum in the process of de-chucking the support plate PLT from the first electrostatic chuck ESC1. That is, in the process of releasing vacuum in the process of de-chucking the support plate PLT from the first electrostatic chuck ESC1, external air may be smoothly introduced into the pass holes PH1-1 and PH1-2 of the support plate PLT through the spaces between the first part PPA1-1 and the second part PPA1-2 and the support plate PLT. The step differences L1 and L2 respectively between the upper surface of the suction part AP and the upper surfaces of the first part PPA1-1 and the upper surface of the second part PPA1-2 may be not less than about 1 mm and not more than about 3 mm. The step difference L1 between the upper surface of the first part PPA1-1 and the upper surface of the suction part AP may be substantially the same as the step difference L2 between the upper surface of the second part PPA1-2 and the upper surface of the suction part AP. For example, the step difference L1 and L2 may be about 2 mm.

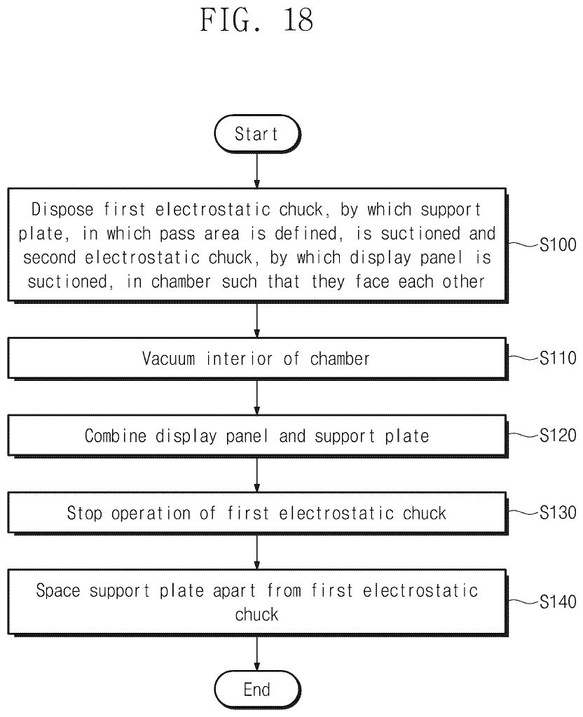

When de-chucking through the first recess HM1 of the first electrostatic chuck ESC1, a space, in which external air may be smoothly introduced into the pass holes PH1-1 and PH1-2 of the support plate PLT, may be secured so that the pressure difference may be effectively reduced, and thus, a defect, by which the component areas TA1 and TA2 (see FIG. 3) are recessed in the display panel DP (see FIG. 3) may be improved. A method for manufacturing a display device according to one or more embodiments of the present disclosure including a process of de-chucking the support plate PLT from the first electrostatic chuck ESC1 will be described in detail with reference to FIGS. 18 to 21.

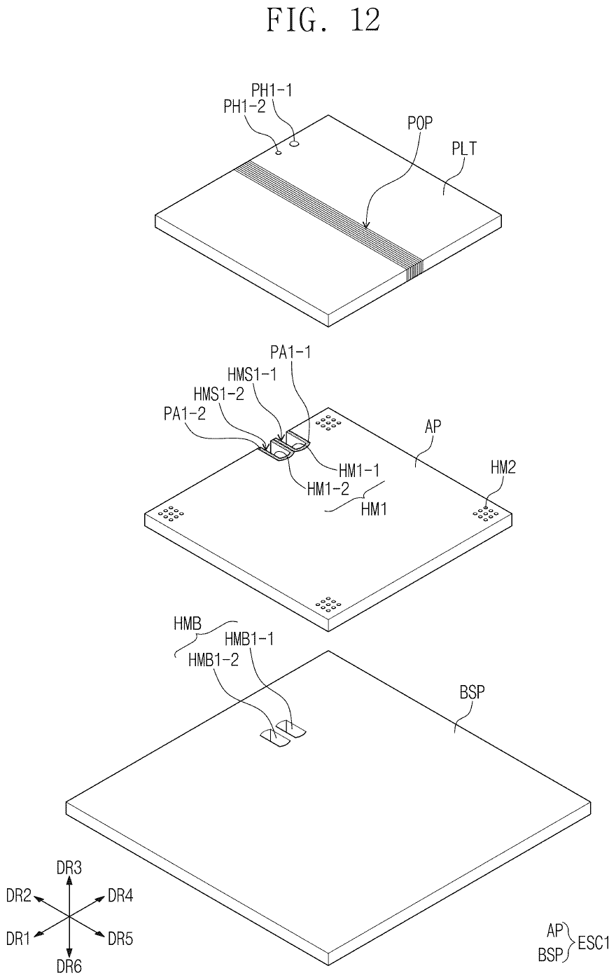

FIG. 12 is an exploded perspective view of the first electrostatic chuck and the support plate illustrated in FIG. 11.

Referring to FIGS. 11 and 12, the first recess HM1 overlaps the pass holes PH1-1 and PH1-2 of the support plate PLT on a plane. For example, in a state in which the support plate PLT is combined on the first electrostatic chuck ESC1, the pass holes PH1-1 and PH1-2 defined on the support plate PLT may overlap the above-described component areas TA1 and TA2 (see FIG. 3).

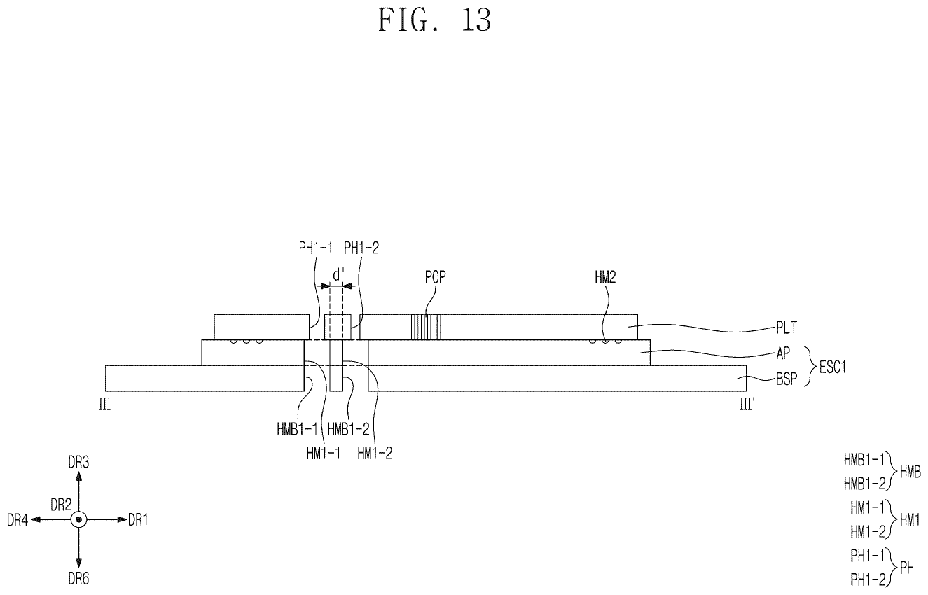

The base part BSP may serve to support the suction part AP. The base part BSP may include ceramic or metal. The base part BSP may include a base recess HMB that overlaps the first recess HM1 on a plane. The base recess HMB may include a first base recess HMB1-1 that overlaps the (1-1)-th recess HM1-1 on a plane, and a second base recess HMB1-2 that overlaps the (1-2)-th recess HM1-2 on the plane. The base recess HMB may be a component that is connected to the first recess HM1. The base recess HMB may pass through at least a portion of the base part BSP. Cross-sectional shapes of the first recess HM1 and the base recess HMB will be described in detail with reference to FIGS. 13 to 17A.

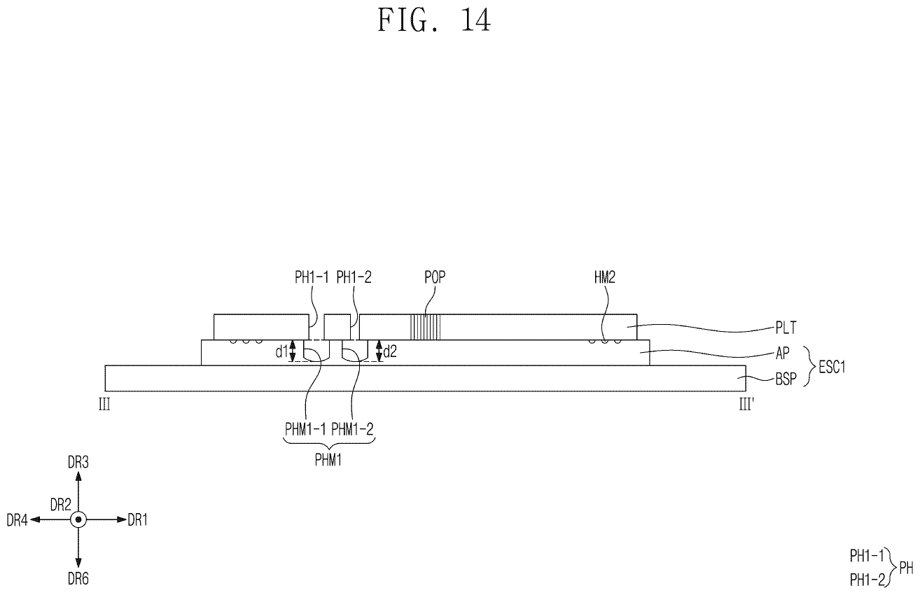

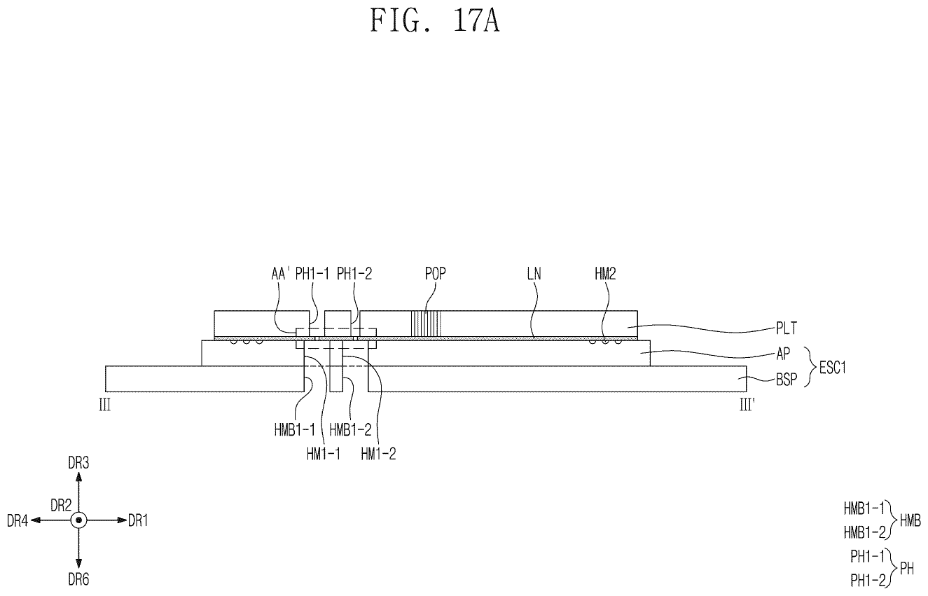

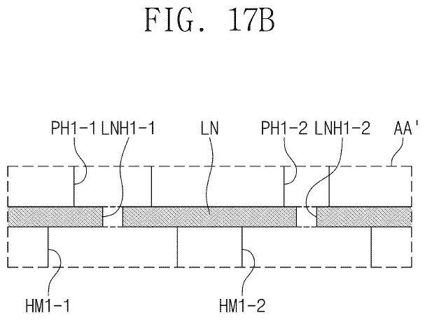

FIGS. 13 to 17A are cross-sectional views taken along the line III-III′ illustrated in FIG. 11, respectively. FIG. 17B is an enlarged cross-sectional view of AA′ of FIG. 17A. FIGS. 14 to 16 illustrate shapes that vary depending on a depth of a first recess HM1 and a depth of a base recess HMB. Unlike in FIGS. 13 to 16, FIG. 17A additionally illustrates a liner LN that is located on a lower surface of the support plate PLT. In the drawings corresponding to the description below, the first part PA1-1 (see FIG. 10A) and the second part PA1-2 (see FIG. 10A) may be omitted. A repeated description of the above-described components will be omitted.

Referring to FIG. 13, in the first electrostatic chuck ESC1 according to one or more embodiments, each of the (1-1)-th recess HM1-1 and the (1-2)-th recess HM1-2 may completely pass through the suction part AP. Each of the first base recess HMB1-1 and the second base recess HMB1-2 may completely pass through the base part BSP. The (1-1)-th recess HM1-1 and the first base recess HMB1-1 may overlap each other when viewed on a plane. Diameters of the (1-1)-th recess HM1-1 and the first base recess HMB1-1 may be the same. The (1-2)-th recess HM1-2 and the second base recess HMB1-2 may overlap each other when viewed on a plane. Diameters of the (1-2)-th recess HM1-2 and the second base recess HMB1-2 may be the same.

The (1-2)-th recess HM1-2 may be spaced apart from the (1-1)-th recess HM1-1 in the first direction DR1. A spacing distance d′ between the (1-1)-th recess HM1-1 and the (1-2)-th recess HM1-2 may be between about 1 mm and about about 5 mm inclusive.

Referring to FIG. 14, unlike in FIG. 13, the first electrostatic chuck ESC1 according to one or more embodiments may not include a base recess HMB, but may include a (1-1)-th recess PHM1-1 and a (1-2)-th recess PHM1-2. Each of a depth d1 of the (1-1)-th recess PHM1-1 and a depth d2 of the (1-2)-th recess PHM1-2 may be not less than about 1 mm and not more than about 40 mm. For example, when the depth d1 of the (1-1)-th recess PHM1-1 is about 40 mm, the (1-1)-th recess PHM1-1 may completely pass through the suction part AP. The depth d1 of the (1-1)-th recess PHM1-1 may be the same as the depth d2 of the (1-2)-th recess PHM1-2. Unlike in FIG. 14, in one or more embodiments, the depth d1 of the (1-1)-th recess PHM1-1 may be different from the depth d2 of the (1-2)-th recess PHM1-2.

The recess PHM1-1 and the (1-2)-th recess PHM1-2 may pass through a portion of the suction part AP. That is, each of the depth d1 of the (1-1)-th recess PHM1-1 and the depth d2 of the (1-2)-th recess PHM1-2 may be less than the thickness of the suction part AP. Each of the depth d1 of the (1-1)-th recess PHM1-1 and the depth d2 of the (1-2)-th recess PHM1-2 may be greater than the depth of each of the plurality of second recesses HM2.

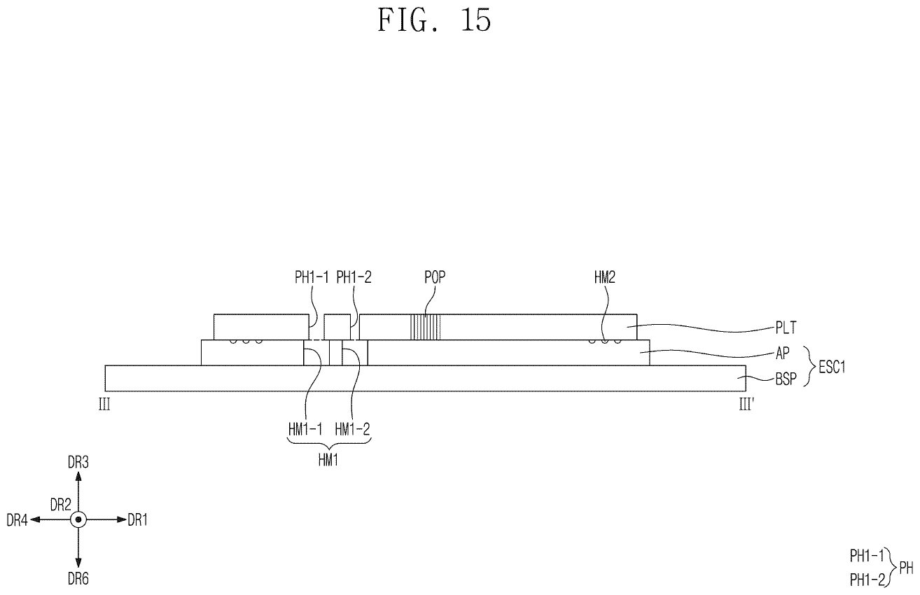

Referring to FIG. 15, the first electrostatic chuck ESC1 according to one or more embodiments may not include the base recess HMB. The (1-1)-th recess HM1-1 and the (1-2)-th recess HM1-2 may completely pass through the suction part AP. That is, each of a depth of the (1-1)-th recess HM1-1 and a depth of the (1-2)-th recess HM1-2 may be substantially the same as the thickness of the suction part AP. In one or more embodiments, a separate base recess may not be formed in the base part BSP.

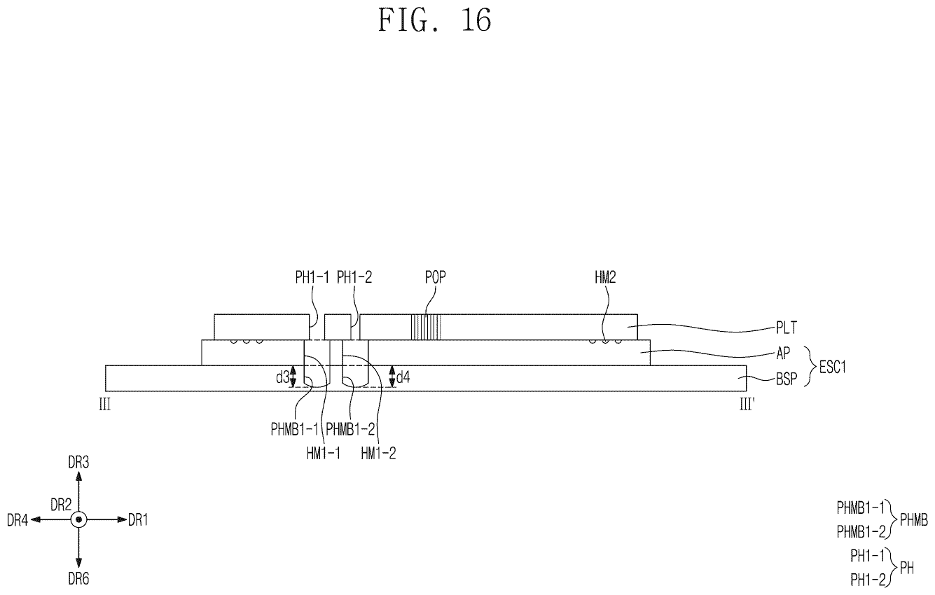

Referring to FIG. 16, the first electrostatic chuck ESC1 according to one or more embodiments may include the base recess HMB. The (1-1)-th recess HM1-1 and the (1-2)-th recess HM1-2 may completely pass through the suction part AP. Each of a first base recess PHMB1-1 and a second base recess PHMB1-2 may pass through a portion of the base part BSP. That is, each of a depth d3 of the first base recess PHMB1-1 and a depth d4 of the second base recess PHMB1-2 may be less than the thickness of the base part HMB. The depth d3 of the first base recess PHMB1-1 and the depth d4 of the second base recess PHMB1-2 may be substantially the same.

Referring to FIG. 17A, the liner LN may be located between the first electrostatic chuck ESC1 and the support plate PLT. The support plate PLT may be directly located on the liner LN. The liner LN is located on the lower surface of the support plate PLT, and thus, the amounts of the external air that is introduced into and discharged from the first pass hole PH1-1 and the second pass hole PH1-2 of the support plate PLT may be controlled during the deposition process.

Referring to FIGS. 17A and 17B together, the liner LN may include a first liner hole LNH1-1 and a second liner hole LNH1-2. The first liner hole LNH1-1 may overlap the (1-1)-th recess HM1-1 and the first pass hole PH1-1. The second liner hole LNH1-2 may overlap the (1-2)-th recess HM1-2 and the second pass hole PH1-2. A diameter of the first liner hole LNH1-1 may be less than a diameter of the first pass hole PH1-1. A diameter of the second liner hole LNH1-2 may be less than a diameter of the second pass hole PH1-2. The first liner hole LNH1-1 and the second liner hole LNH1-2 have smaller diameters than those of each of the first pass hole PH1-1 and the second pass hole PH1-2, and thus the amounts of air introduced into or discharged from the first pass hole PH1-1 and the second pass hole PH1-2 may be controlled by the first electrostatic chuck ESC1 during the process of chucking or de-chucking the support plate PLT.

Hereinafter, a method for manufacturing a display device using a deposition apparatus according to one or more embodiments of the present disclosure will be described. A repeated description of the above-described configuration will be omitted.

FIG. 18 is a flowchart of a method for manufacturing a display device according to one or more embodiments of the present disclosure. FIGS. 19 to 21 are cross-sectional views illustrating a part of a method for manufacturing a display device according to one or more embodiments of the present disclosure.

Referring to FIG. 18, a method for manufacturing a display device according to one or more embodiments of the present disclosure includes an operation S100 of positioning a first electrostatic chuck, by which a support plate, in which a pass hole is defined, is suctioned, and positioning a second electrostatic chuck, by which a display panel is suctioned, in a chamber such that they face each other, an operation S110 of vacuuming an interior of the chamber, an operation S120 of combining the display panel and the support plate, an operation S130 of stopping an operation of the first electrostatic chuck, and an operation S140 of separating/spacing the support plate from the first electrostatic chuck.

Referring to FIG. 19, a deposition apparatus DPD according to one or more embodiments may include a chamber CB, a first electrostatic chuck ESC1, and a second electrostatic chuck ESC2.

The chamber CB may form a difference in air pressure from the outside by controlling an amount of air in an interior of the chamber CB. The chamber CB may be a closed space. A first electrostatic chuck ESC1 and a second electrostatic chuck ESC2 are located in the chamber CB.

In the method for manufacturing a display device according to one or more embodiments, the second electrostatic chuck ESC2 is located in the chamber CB to face the first electrostatic chuck ESC1. The second electrostatic chuck ESC2 facing the first electrostatic chuck ESC1 may mean that the support plate PLT and the display panel DP overlap each other on a plane. A configuration of the second electrostatic chuck ESC2 may be the same as that of the first electrostatic chuck ESC1. The second electrostatic chuck ESC2 may suction the display panel DP.

The method for manufacturing a display device according to one or more embodiments includes an operation of vacuuming an interior of the chamber CB after the second electrostatic chuck ESC2 is located in the chamber CB to face the first electrostatic chuck ESC1. Because the chamber CB is a closed space, the interior of the chamber CB may be continuously converted into a vacuum environment.

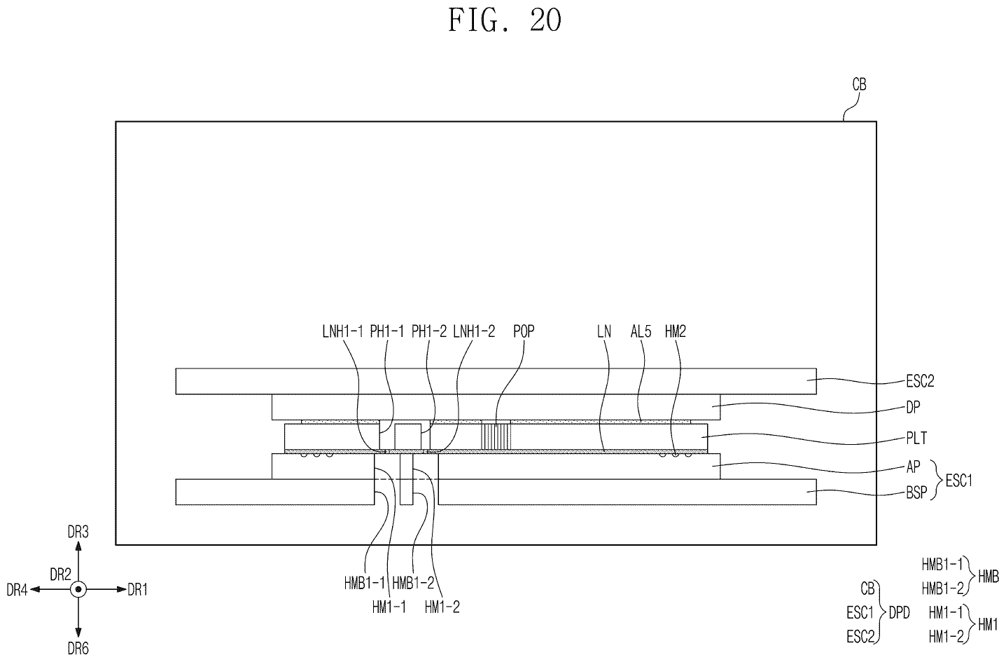

Referring to FIG. 20, a method for manufacturing a display device according to one or more embodiments includes an operation for combining the display panel DP and the support plate PLT after the operation for vacuuming the interior of the chamber CB. A fifth adhesive layer AL5 may be located on the support plate PLT. The fifth adhesive layer AL5 may adhere the display panel DP and the support plate PLT to each other. In the operation of combining the display panel DP and the support plate PLT, the second electrostatic chuck ESC2 may move the display panel DP in the sixth direction DR6 such that the display panel DP directly contacts the fifth adhesive layer AL5. In a state, in which the second electrostatic chuck ESC2 is moved and the display panel DP and the support plate PLT are combined with each other, the first pass hole PH1-1 and the second pass hole PH1-2 are maintained in vacuum or a low pressure (e.g., atmospheric pressure).

The method for manufacturing a display device according to one or more embodiments may include an operation of stopping the operation of the first electrostatic chuck ESC1 after the operation of combining the display panel DP and the support plate PLT. The stopping of the operation of the first electrostatic chuck ESC1 means releasing a pressure due to a difference between electrostatic force and atmospheric pressure that act between the first electrostatic chuck ESC1 and the support plate PLT, and releasing a vacuum state in the interior of the chamber CB, thereby creating an environment, such as an atmospheric pressure. Accordingly, air is introduced into the first pass hole PH1-1 and the second pass hole PH1-2, which were maintained in a vacuum state or a low pressure state, thereby creating an environment, such as the atmospheric pressure. A time interval between the operation of combining the display panel DP and the support plate PLT and the operation of stopping the operation of the first electrostatic chuck ESC1 may be between about 1 second and about 3 seconds inclusive. For example, after about two seconds after bonding the display panel DP and the support plate PLT, the operation of the first electrostatic chuck ESC1 may be stopped. When a time interval between the operation for combining the display panel DP and the support plate PLT and the operation for stopping the operation of the first electrostatic chuck ESC1 is less than about one second, an adhesion force between the display panel DP and the support plate PLT may not be sufficient. When a time interval between an operation for combining the display panel DP and the support plate PLT and the operation for stopping the operation of the first electrostatic chuck ESC1 exceeds about 3 seconds, the display panel DP may be deformed by a pressure due to vacuum.

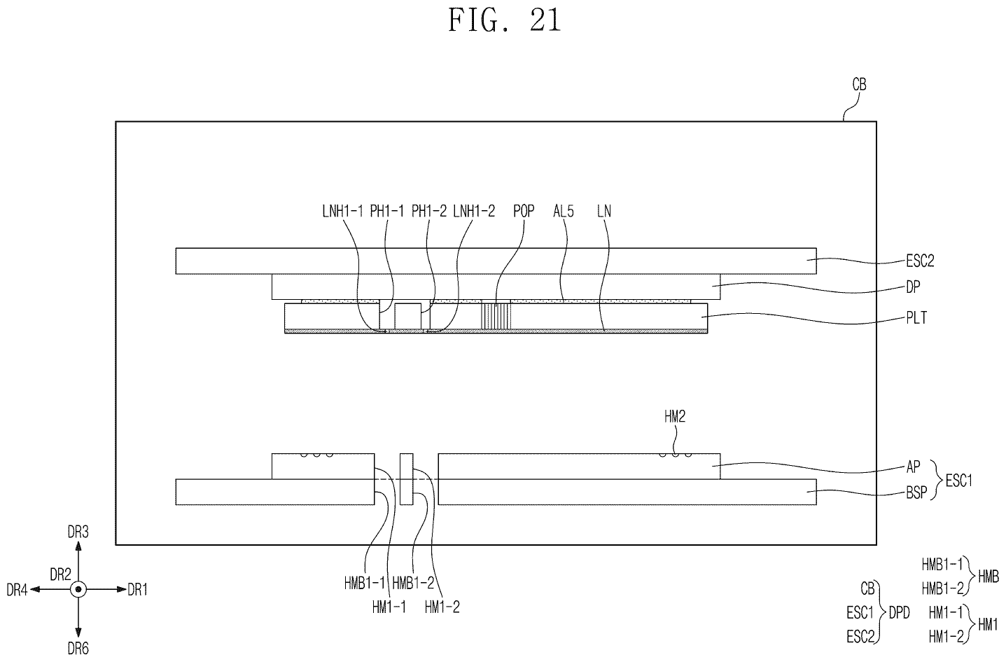

Referring to FIG. 21, the method for manufacturing a display device according to one or more embodiments includes an operation of separating the support plate PLT from the first electrostatic chuck ESC1. The separation of the support plate PLT from the first electrostatic chuck ESC1 may mean moving the second electrostatic chuck ESC2 in the third direction DR3. A liner LN may be located on a lower surface of the support plate PLT.

The display panel DP includes main display area MA (see FIG. 3) and component areas TA1 and TA2 (see FIG. 3), which have a transmittance that is higher than that of the main display area MA (see FIG. 3) and which respectively overlap the pass holes PH1-1 and PH1-2 when the display panel DP and the support plate PLT are combined with each other on a plane. The main display area MA (see FIG. 3) may be an area that overlaps the display area DA of FIG. 1. The component areas TA1 and TA2 (see FIG. 3) may be areas that respectively overlap the sensor module SNM and the camera module CAM of FIG. 1.

Hereinafter, an evaluation of whether a display device manufactured through a deposition apparatus and a comparative sample deposition apparatus according to one or more embodiments of the present disclosure is defective will be described in detail.

The deposition apparatus according to one or more embodiments includes the first electrostatic chuck ESC1 and the second electrostatic chuck ESC2 illustrated in FIG. 19.

The deposition apparatus according to one or more embodiments (e.g., First Embodiment in Table 1) is formed such that there is no step difference between the upper surface of the suction part AP and the upper surfaces of the first part PA1-1 and the second part PA1-2 as illustrated in FIG. 10B.

In the deposition apparatus of one or more other embodiments (e.g., Second Embodiment in Table 1), as illustrated in FIG. 10C, the step difference L1 and L2 of the upper surfaces of the first part PPA1-1 and the second part PPA1-2 and the upper surface of the suction part AP are formed to be equal to about 1.527 mm.

The deposition apparatuses of the embodiments are formed so that the first recess HM1 completely passes through the suction part AP, and the base recess HMB is formed to completely pass through the base part BSP. Compared to the deposition apparatus of one or more embodiments (e.g., First Embodiment in Table 1), the comparative example deposition apparatus only has differences in that the first recess HM1 and the base recess HMB are not defined, and the remaining conditions are manufactured the same.

The following table Table 1 shows the results of combining the display panel and the support plate by performing an operation of positioning the first electrostatic chuck, by which the support plate with the pass hole defined in the chamber is suctioned, and the second electrostatic chuck, by which the display panel is suctioned, to face each other, an operation of vacuuming the interior of the chamber, an operation of combining the display panel and the support plate, an operation of stopping the operation of the first electrostatic chuck, and an operation of spacing the support plate apart from the first electrostatic chuck by using the deposition apparatuses of one or more embodiments (e.g., First Embodiment and Second Embodiment), and a comparative example (e.g., Comparative Example). Table 1 illustrates the observation results by defining a degree to which the display panel is recessed as “a degree of deformation,” while no deformation of the display panel being referred to as 100%, based on visual observation for each of the first component area and the second component areas of the display panel.

TABLE 1

| | Degree of deformation (%) | Degree of deformation (%) |
|---|---|---|
| | of first component area | of second component area |
| First | 52.1 | 75.0 |
| embodiment | | |
| Second | 87.7 | 86.6 |
| embodiment | | |
| Comparative | 23.0 | 8.0 |
| example | | |

Referring to Table 1, it may be seen that the degree of deformation of the embodiments (e.g., First Embodiment and Second Embodiment) is improved as compared to that of the comparative example. In the deposition apparatuses of the embodiments, because the first electrostatic chuck includes a first recess, it is interpreted that air is smoothly introduced into the first pass hole and the second pass hole of the support plate through the first recess in the process of releasing the vacuum by stopping the operation of the first electrostatic chuck after combining the display panel and the support plate whereby the pressure difference is effectively released so that the display is less deformed. On the other hand, in the deposition apparatus of the comparative example, because the first electrostatic chuck does not include the first recess, it is interpreted that the air is not smoothly introduced into the first pass hole and the second pass hole of the support plate in the operation of spacing the support plate apart from the first electrostatic chuck after combining the display panel and the support plate whereby the difference in air pressure is not sufficiently released, so that the display panel may be deformed to a greater degree. Although the present disclosure has been described with reference to the embodiments, it will be appreciated by an ordinary skilled in the art, to which the present disclosure pertains, that the present disclosure may be modified and changed within the scope of the appended claims without departing from the spirit of the present disclosure. Therefore, the present disclosure should not be limited to the detailed description of the specification, but should be determined by the claims, with functional equivalents thereof to be included therein.

The deposition apparatus of one or more embodiments of the present disclosure includes a first recess, and a plurality of second recesses that are spaced apart from the first recess, and may improve the yield rate by allowing a fixed target panel to be suitably spaced apart from the deposition apparatus.

The method for manufacturing a display device of embodiments of the present disclosure may improve the yield rate by allowing a fixed target panel to be suitably spaced apart from the deposition apparatus by using the deposition apparatus including a first recess, and a plurality of second recesses that are spaced apart from the first recess.

What is claimed is:

1. A deposition apparatus comprising:
a first electrostatic chuck configured to suction a support plate defining a pass hole, the first electrostatic chuck comprising:
a base part; and
a suction part on the base part, the suction part defining:
a first recess for overlapping the pass hole; and
second recesses spaced apart from the first recess, and having diameters that are less than a diameter of the first recess.

2. The deposition apparatus of claim 1, wherein the first recess completely passes through the suction part.

3. The deposition apparatus of claim 2, wherein the base part defines a base recess overlapping the first recess.

4. The deposition apparatus of claim 3, wherein the base recess completely passes through the base part.

5. The deposition apparatus of claim 1, wherein the suction part comprises polyimide.

6. The deposition apparatus of claim 1, wherein the base part comprises ceramic or metal.

7. The deposition apparatus of claim 1, wherein a profile of the suction part on a plane is less than that of the base part.

8. The deposition apparatus of claim 1, wherein the suction part further comprises a first surface parallel to a first direction, and
wherein the first recess comprises a side recess extending from the first surface.

9. The deposition apparatus of claim 8, wherein the first recess comprises a (1-1)-th recess, and a (1-2)-th recess spaced apart from the (1-1)-th recess in the first direction.

10. The deposition apparatus of claim 9, wherein depths of the (1-1)-th recess and the (1-2)-th recess are between about 1 mm and about 40 mm.

11. The deposition apparatus of claim 9, wherein a distance between the (1-1)-th recess and the (1-2)-th recess in the first direction is between about 1 mm and about 5 mm.

12. The deposition apparatus of claim 9, wherein the suction part comprises:
a first part surrounding the (1-1)-th recess on a plane; and
a second part surrounding the (1-2)-th recess on the plane.

13. The deposition apparatus of claim 12, wherein a height of the first part is substantially equal to a height of the second part.

14. The deposition apparatus of claim 12, wherein the first part and the second part do not comprise polyimide.

15. The deposition apparatus of claim 12, wherein an upper surface of the first part and an upper surface of the second part are lower than an upper surface of the suction part.

16. The deposition apparatus of claim 15, wherein a step difference between the upper surface of the suction part and the upper surfaces of the first part or the second part is between about 1 mm and about 3 mm.

17. A method for manufacturing a display device, the method comprising:
positioning, in a chamber, a first electrostatic chuck comprising a base part, and a suction part on the base part and defining a first recess and second recesses, diameters of the second recesses being less than a diameter of the first recess, for suctioning a support plate defining a pass hole overlapping the first recess;
positioning, in the chamber, a second electrostatic chuck for suctioning a display panel having a main display area, and a component area having a transmittance that is higher than that of the main display area, the first electrostatic chuck and the second electrostatic chuck facing each other;
vacuuming an interior of the chamber;
combining the display panel and the support plate such that the component area overlaps the pass hole;
stopping an operation of the first electrostatic chuck; and
spacing the support plate apart from the first electrostatic chuck.

18. The method of claim 17, wherein a time interval between the combining of the display panel and the support plate and the stopping of the operation of the first electrostatic chuck is between about 1 second and about 3 seconds.

19. The method of claim 17, wherein the first recess comprises a (1-1)-th recess, and a (1-2)-th recess spaced apart from the (1-1)-th recess in a first direction, and completely passes through the suction part, and
wherein the base part defines a base recess overlapping the first recess and completely passing through the base part.

20. An electronic device for providing an image, and comprising a display device manufactured by:
positioning, in a chamber:
a first electrostatic chuck comprising a base part, and a suction part defining a first recess and second recesses having diameters that are less than that of the first recess on the base part, for suctioning a support plate defining a pass hole to overlap the first recess; and
a second electrostatic chuck for suctioning a display panel having a main display area, and a component area having a transmittance that is higher than that of the main display area, the first electrostatic chuck and the second electrostatic chuck facing each other;
vacuuming an interior of the chamber;
combining the display panel and the support plate such that the component area overlaps the pass hole;
stopping an operation of the first electrostatic chuck; and
spacing the support plate apart from the first electrostatic chuck.
